(19) United States
(12) Patent Application Publication
(10) Pub. No.: US 2026/0113898 A1
(43) Pub. Date: Apr. 23, 2026

(54) PROTECTED ELECTRONIC DEVICE FOR IMMERSION COOLING ENVIRONMENT AND METHODS FOR MAKING SAME

(71) Applicant: MTS IP Holdings Ltd, George Town, Grand Cayman (KY)

(72) Inventors: Phillip E. Tuma, Faribault, MN (US); Ioannis Manousakis, Zürich (CH); Jimil Shah, McKinney, TX (US); Joshua Hemelgarn, Zurich (CH); Luke Gregory, Mercer Island, WA (US)

(21) Appl. No.: 19/485,910

(22) PCT Filed: May 20, 2024
(86) PCT No.: PCT/US2024/030241

§ 371 Date: Nov. 19, 2025

Related U.S. Application Data
(60) Provisional application No. 63/503,401, filed on May 19, 2023.
(60) Provisional application No. 63/503,405, filed on May 19, 2023.
(60) Provisional application No. 63/505,129, filed on May 31, 2023.
(60) Provisional application No. 63/514,103, filed on Jul. 17, 2023.
(60) Provisional application No. 63/578,866, filed on Aug. 25, 2023.
(60) Provisional application No. 63/581,260, filed on Sep. 7, 2023.

(51) Int. Cl. H05K 7/20

(52) U.S. Cl. CPC H05K 7/20809

(57) ABSTRACT

A computing system includes an electronic device connected to a substrate via electrical interconnects. The system includes one or more protective features to reduce the exposure of the electrical interconnects to the coolant liquid of a two-phase immersion cooling system. For example, a sealant may be applied along the edges of the device such that the device, the substrate, 2024/243146 and the sealant together form a cavity to trap gas bubbles, which surround the electrical interconnects and displace the coolant liquid. In another example, an underfill may encapsulate the electrical interconnects, thus providing a physical barrier between the electrical interconnects and the coolant liquid. In another example, a protective coating may be applied to a portion of the device to suppress boiling of the coolant liquid at that portion. The coating is thermally insulating, hydrophobic and/or oleophobic, and provides a smooth surface with little to no nucleation sites for boiling.

### CROSS-REFERENCE TO RELATED APPLICATION(S)

This application claims the priority benefit, under 35 U.S. C. 119(e), of U.S. Application No. 63/581,260, filed Sep. 7, 2023 and entitled, “EDGE SEALED ELECTRONIC DEVICE FOR IMMERSION COOLING ENVIRONMENT AND METHODS FOR MAKING SAME,” U.S. Application No. 63/578,866, filed Aug. 25, 2023 and entitled, “PROTECTIVE COATING FOR ELECTRONIC DEVICES IN IMMERSION COOLING SYSTEMS,” U.S. Application No. 63/514,103, filed Jul. 17, 2023 and entitled, “EDGE SEALED ELECTRONIC DEVICE FOR IMMERSION COOLING ENVIRONMENT AND METHODS FOR MAKING SAME,” U.S. Application No. 63/505,129, filed May 31, 2023 and entitled, “PROTECTIVE COATING FOR ELECTRONIC DEVICES IN IMMERSION COOLING SYSTEMS,” U.S. Application No. 63/503,405, filed May 19, 2023 and entitled, “Application of Underfilling BGA Devices in Two Phase Immersion Cooling,” and U.S. Application No. 63/503,401, filed May 19, 2023 and entitled, “Edge Bonding for Immersion Systems.” Each of the aforementioned applications is incorporated herein by reference in its entirety.

### BACKGROUND

Two-phase immersion cooling is a liquid cooling technique that utilizes a liquid-to-gas phase transition to remove heat from a heat-generating component, such as a processor or, more generally, an electronic device of a computing system. This is typically accomplished using a tank to submerge the heat-generating component in a pool of coolant liquid where the coolant liquid is a dielectric with a relatively low boiling point (e.g., 50° C.). During operation, the coolant liquid in direct contact with the heat-generating component vaporizes (i.e., boils), producing coolant vapor that rises upwards within the tank. The coolant vapor thereafter transfers heat to a heat exchanger disposed above the coolant liquid, thus causing the coolant vapor to condense back to a liquid and thereafter fall into the pool of coolant liquid below. A two-phase immersion cooling system may be used to cool high density computing systems, such as an array of servers in a data center.

### SUMMARY

The Inventors have recognized and appreciated that two-phase immersion cooling provides an energy efficient approach to cool a computing system, such as a high-density computing system. However, the Inventors have also recognized that submerging the electronic components of a computing system in the coolant liquid of a two-phase immersion cooling system can adversely affect the performance of the computing system and, in some instances, cause the computing system to fail prematurely.

A computing system typically includes a printed circuit board (PCB) or a printed circuit board assembly (PCBA) with multiple surface-mounted electronic devices. The electronic devices include, but are not limited to, a computer processor unit (CPU), a graphics processor unit (GPU), a data processing unit (DPU), a field-programmable gate array (FPGA), an application-specific integrated circuit (ASIC), memory (e.g., rapid access memory), and, more generally, any electronic component with an integrated circuit or a transistor. These surface-mounted electronic devices are mounted to the PCB or PCBA using electrical interconnects, such as a ball grid array (BGA), a pin grid array (PGA), a land grid array (LGA), and/or the like. The electrical interconnects between the device and the PCB or PCBA are particularly sensitive to alterations in the working environment (e.g., air, coolant liquid) and prone to failure when submerged in the coolant liquid of a two-phase immersion cooling system.

In particular, the electrical interconnects generate an appreciable amount of heat, which is typically sufficient to boil the coolant liquid of a two-phase immersion cooling system. As the coolant liquid boils, contaminants (e.g., hydrocarbons, particles, solubles) suspended in the coolant liquid preferentially deposit and accumulate onto these electrical interconnects via distillation. As an illustrative example, FIG. 1A shows a computing system 10 with a device 12 mounted to a substrate 16 via a ball grid array (BGA) 14, which includes an array of solder balls to join respective electrical contacts of the device 12 to corresponding contact pads on the substrate (e.g., PCB) 16. FIGS. 1B-1D show the computing system 10 submerged in a coolant liquid 90, which infiltrates and floods the space between the device 12 and the substrate 16 where the BGA 14 is located. During operation, the heat generated by the device 12 may be dissipated to the coolant liquid 90, thus causing the coolant liquid 90 to boil and produce coolant vapor 94. The central portion 92 of the BGA 14 generates the most heat. This, in turn, causes contaminants to deposit and accumulate onto the central portion 92 of the BGA 14, which can lead to electrical related failures, such as a hard short between two solder balls of opposing polarity or increasing signal losses due to dielectric properties.

For example, the coolant liquid typically includes hydrocarbon contaminants originating, for example, from various cable insulation, wire insulation, electrical isolators, O-rings, gaskets and/or the like submerged in the coolant liquid. Although hydrocarbon contaminants are electrically insulating and inert, they can nevertheless facilitate undesirable interactions between other contaminants and the electrical interconnects of a device.

For instance, devices are often mounted to a PCB or PCBA using a solder reflow process where solder flux (e.g., a no-clean solder flux) is used to facilitate the reflow of solder. FIG. 2A shows that before a solder reflow process occurs, solder flux typically includes a mixture of resin, activators (e.g., halides, a weak organic acid (WOA)), solvent, and other additives. During the solder reflow process, the solder flux is exposed to an elevated temperature, resulting in the removal of the solvent and a portion of the activators due to the activators being volatized beyond their melting point. However, some of the activators may nevertheless remain after the resin cures.

The solder reflow process typically leaves behind a benign residue of solder reflux containing a relatively low concentration of electrochemically active ionic compounds near and/or on the electrical interconnects. For example, FIG. 2B shows an example solder joint 18 formed on the substrate 16 with a soldering residue 19a. The soldering residue 19a typically comprises cured resin/rosin matrices that encapsulate and suspend the activators. The matrices correspond to the mechanically hard portion of the solder flux.

When the soldering residue 19a is exposed to the coolant liquid 90, the coolant liquid 90 may gradually break down the matrices of the soldering residue 19a over time exposing and releasing the activators. For example, FIG. 2C shows an aged form of the soldering residue 19a represented by the soldering residue 19b. FIG. 2D shows a photograph of an aged soldering residue 19b surrounding a solder ball of a BGA 14 due to exposure to coolant liquid. As shown, the soldering residue 19b includes clear flux rosin with cracks and delaminated portions. The activators are electrochemically active compounds and, when released, can readily dissolve in the hydrocarbon contaminants present in the coolant liquid.

Thereafter, the hydrocarbon contaminants can deposit at higher concentrations on the heat generating portions of the computing system (e.g., the central portion 92 in FIG. 1B) as the coolant liquid 90 boils. Said another way, the hydrocarbon contaminants may deposit due to distillation near and/or on the electrical interconnects (e.g., the BGA 14). FIG. 2E shows a photograph where the hydrocarbon contaminants are deposited as an oil 20 that engulfs multiple solder balls with respective soldering residues 19b in the BGA 14.

The accumulation of mobile electrochemically active compounds can gradually lower the impedance, resulting in greater leakage, parasitic losses, and/or undesirable capacitance. Over time, the electrochemically active compounds can cause device failure due to bitflips. Additionally, the compounds can lead to an electrical hard short between the electrical interconnects, particularly if the electrical interconnects formed by the BGA 14 operate at relatively higher operating voltages (e.g., 3.3V, or 5V). For reference, FIG. 2F shows an example BGA 14 where the respective solder balls are surrounded by pristine soldering residue 19a (i.e., clean, uncracked circles around the solder balls).

It should be appreciated that the foregoing failure mechanism is not limited only to devices with a BGA. In another example, a power field effect transistor (FET) includes multiple electrical pins, which are often soldered to corresponding contact pads or through-holes on a PCB in a similar manner as the device 12 described above. More generally, this failure mechanism may occur for any device that is electrically coupled to a substrate via multiple electrical interconnects.

In another example, some commonly used coolant liquids can react with water to form acids or acidic salts that corrode the metal in the electrical interconnects and, in turn, generate metallic salts suspended in the coolant liquid. These metallic salts can thereafter migrate in the presence of an electric field (e.g., the electric fields between the electrical interconnects), thus causing the formation and growth of metallic dendrites between the electrical interconnects. The growth of these dendrites can also lead to an electrical hard short between the electrical interconnects.

Water can be introduced into a tank of the two-phase immersion cooling system, for example, as water vapor when an inlet valve coupled to the tank is opened to the ambient environment to alleviate negative pressure conditions within the tank. some of the foregoing compounds can corrode metals in the electronic devices. One common coolant liquid is fluoroketone, which can react with water to form the following compounds: diol (CF₃CF₂C(OH)2CF(CF₃)₂), diol anion (CF₃CF₂C(OH)O—CF(CF₃)₂), perfluoropropionic acid ((PFPA)CF₃CF₂COOH), PFPA anion (CF₃CF₂COO—), carbanion ion (—CF(CF₃)₂), HFC-227 (CF₃CFHCF₃), and/or hexafluoropropylene (HFP) (CF₂═CFCF₃).

Additionally, signals transmitted via the electrical interconnects often suffer from decreased signal integrity when coolant liquid is present. Herein, the signal integrity refers to the quality of an electrical signal, which can degrade as the signal propagates across different media (e.g., an electrical interface) due to noise, distortion, and/or loss. In practice, a signal with a relatively high signal integrity has a lower likelihood or, in some instances, no likelihood of causing an error or failure in the computing system. In contrast, a signal with a relatively low signal integrity is likely to cause an error or failure in the computing system.

The adverse effects on signal integrity are primarily due to the coolant liquid having a higher dielectric constant than air. For example, air has a static dielectric constant of about 1 and the coolant liquids used in a two-phase immersion cooling system (e.g., fluoroketone), has a static dielectric constant of about 1.8-2. The change in dielectric constant can change the characteristic impedance of the electrical interconnects, which, in turn, can create an impedance mismatch between the electrical interconnects and the transmission lines connected by the electrical interconnects, resulting in greater reflection losses and a reduction in signal integrity.

In addition to the above problems with contamination, the Inventors also recognized the assembly of some of the electronic devices can vary due to manufacturing tolerances. For example, some electronic devices include pins that are inserted through corresponding through-holes on the PCB. If a gap exists between the portion of the PCB forming the through-hole and the pin, the coolant liquid can pass through the gap and/or settle between the PCB and the pin. This, in turn, creates a dielectric layer that can lead to power loss, network loss, and/or other signal integrity issues.

The present disclosure is thus directed to various inventive implementations of a protected electronic device (also referred to herein as a “device”) configured for immersion in the coolant liquid of a two-phase immersion cooling system. The present disclosure is also directed to computing systems that include the devices disclosed herein and methods for assembling the computing system.

In one approach, a sealant is applied along at least a portion of the edges of a device to form an edge bond that seals at least some of the gaps formed between the device and an underlying substrate supporting the device (e.g., a PCB, or PCBA). The device, the substrate, and the sealant of the computing system together form a cavity containing the electrical interconnects that electrically couple the device to the substrate. The device may trap one or more bubbles of a gas (e.g., air, coolant vapor) within the cavity. The bubble(s) of gas may reduce or, in some instances, mitigate exposure of the electrical interconnects to coolant liquid, which, in turn, improves the performance and lifetime of the device. In some implementations, the bubbles of gas may prevent the failure mechanisms and/or the degradation mechanisms to signal integrity associated with the exposure of the electrical interconnects to coolant liquid described above. The bubbles of gas may be trapped within the cavity in several ways.

In one example, bubbles of coolant vapor and/or air from other electronic components and/or devices disposed below the device may flow into the cavity through an opening formed along the edge bond. The bubbles may, in turn, displace the coolant liquid between the device and the substrate and, hence, around the electrical interconnects, thus limiting exposure to contaminants suspended in the coolant liquid. The opening along the edge bond may also provide a way to regulate the pressure within the cavity, thus reducing or, in some instances, preventing an undesirable buildup of pressure within the cavity during operation.

In another example, the heat generated by the electrical interconnects between the device and the substrate may boil coolant liquid initially present in the cavity. The resultant coolant vapor may, in turn, become trapped in the cavity and either push out any remaining coolant liquid within the cavity through the opening in the edge bond and/or prevent coolant liquid outside the device from entering the cavity.

In yet another example, bubbles of air may be initially trapped in the cavity when immersing a computing system with the device disclosed herein into the coolant liquid. This may be accomplished by immersing the computing system into the coolant liquid and placing the computing system in its desired orientation (e.g., with the opening disposed towards the bottom of the device) quickly such that any bubbles of gas (e.g., air) trapped within the cavity are unable to escape the cavity (e.g., through the opening along the edge bond). Alternatively, all of the edges of the device may be sealed with a sealant while the device is in a gaseous environment so that any gas initially trapped within the cavity remains trapped after the computing system is immersed in the coolant liquid.

In one aspect, the sealant may form an edge bond that extends around an appreciable portion of the edges of the device to limit entry of coolant liquid into the cavity caused by, for example, disturbances to the meniscus of vapor in the cavity due to bubbles from other components and/or devices located below. For example, if the device is shaped as a rectangle or a square and oriented vertically when deployed in the coolant liquid, the sealant may be applied along all of the top edge, the left-side edge, and the right-side edge. The sealant may further be applied along the bottom edge such that only one small opening (e.g., an opening with a width less than 1 mm) is formed. The opening may be formed, for example, by not applying the sealant to a portion of the edges of the device or removing portions of the sealant after application, e.g., by drilling or piercing the sealant to form the opening. It should be appreciated that, in some implementations, the sealant may be applied to all the edges of the device, thus preventing fluid from moving between the cavity and the surrounding environment.

In another aspect, the coolant liquids used in two-phase immersion cooling systems typically have a relatively low surface tension and can thus readily wet various surfaces. This, in turn, means the coolant liquid is prone to infiltrating, via wicking, small crevices formed, for example, between the sealant and the device or between the sealant and the substrate. As the coolant liquid wicks along a surface, it may, in turn, evaporate resulting in the deposition of contaminants. Thus, in some implementations, an oleophobic coating may be applied to the surfaces of the device, the substrate, and the sealant forming the cavity as well as any components disposed within the cavity, such as the electrical interconnects, to reduce or, in some instances, prevent the coolant liquid from wetting the surfaces of the computing system forming the cavity and thus the migration of contaminants (e.g., hydrocarbon contaminants) into the cavity. In some implementations, the oleophobic coating may be formed from a cross-linked fluoropolymer. More generally, the oleophobic coating may formed from various fluoropolymers including, but not limited to, 3M™ Novec™ 2708 and 3M™ Electronic Grade Coating (EGC)-2788.

In yet another aspect, the cavity may be extended in size to provide a larger gap between the sealant and the electrical interconnects between the device and the substrate. In this manner, any contaminants that migrate into the cavity along the sealant (e.g., via the coolant liquid wetting the small crevices described above) may be further separated from the electrical interconnects. This, in turn, increases the lifetime of the device since the contaminants should traverse a greater distance before adversely affecting the electrical interconnects. A large gap may be provided by including an extension plate mounted to the device (e.g., the lid of the device). The extension plate may extend from the edges of the device over the substrate. The sealant may thus be applied to the edges of the extension plate and the substrate to limit entry of coolant liquid into the cavity. In this example, the opening formed along the edge bond is provided between the extension plate and the substrate.

In another approach, an underfill, such as a low dielectric loss epoxy, may be used to fill the interstitial space in and around the electrical interconnects. The underfill may thus provide a barrier that prevents exposure of the electrical interconnects to the coolant liquid, which in turn prevents the deposition of contaminants and electrochemical migration. Additionally, the underfill may be formed from a material with more desirable dielectric properties than the coolant liquid, thus preserving the signal integrity of any signals transmitted by the electrical interconnects.

In yet another approach, a protective coating (also referred to herein as a “coating”) may be applied to at least a portion of an electronic device configured for immersion in a coolant liquid of a two-phase immersion cooling system to reduce or, in some instances, prevent damage and/or failure due to contamination and/or unwanted to penetration of coolant liquid. In particular, the coating may suppress boiling of the coolant liquid at locations where the coating is applied. This may be accomplished, in part, by the coating providing a smooth surface with little to no nucleation sites for boiling, being thermally insulating thus limiting heat dissipation to the coolant liquid, and being hydrophobic and/or oleophobic to repel water and oils, respectively, away from the coating.

In one example implementation, a system comprises a two-phase immersion cooling system comprising a tank defining a tank volume configured to contain a coolant liquid, and a computing system disposed within the tank volume and configured to be submerged in the coolant liquid where the computing system comprises a substrate, a device including an integrated circuit, a plurality of electrical interconnects to electrically couple the device to the substrate, and a sealant applied to the substrate and the device, wherein the sealant is disposed along at least a portion of each edge of the device such that the sealant, the device, and the substrate together form a cavity containing the plurality of electrical interconnects, and the cavity is configured to trap one or more bubbles of a gas when the computing system is submerged in the coolant liquid.

The device may have a shape that is one of a rectangle or a square, when the computing system is submerged in the coolant liquid, the device may be oriented vertically and has a top edge, a right-side edge joined to the top edge, a bottom edge joined to the right-side edge, and a left-side edge joined to the bottom edge and the top edge, and the sealant may be disposed along all of the top edge, the left-side edge, and the right-side edge and along only a portion of the bottom edge to provide at least one opening into the cavity along the bottom edge. The at least one opening may be a single opening having a width less than or equal to about 5 millimeters. The width may be less than or equal to about 2 millimeters. The width may be less than or equal to about 1 millimeters. The at least one opening may be a single opening having a height less than or equal to about 10 millimeters. The height may be less than or equal to about 5 millimeters. The height may be less than or equal to about 2 millimeters. The at least one opening may be a single opening centered along the bottom edge. The at least one opening may include two or more openings evenly distributed along the bottom edge. The computing system may further include a plug disposed in the opening to seal the opening. The plug and the sealant may be formed from different materials. The sealant may include Zymet UA-2605-B and the plug may include Zymet UA-2701. The sealant may be disposed along all of each edge of the device. The sealant may include at least one of 3M™ Scotch-Weld DP420, Zymet X2821, Zymet UA-2605-B, Zymet UVE-1017-2, Zymet CN-1780-5, Zymet X2824, or Zymet UA-2701. The sealant may have a dielectric constant less than 1.8.

The system may further include an oleophobic coating, disposed at least on respective surfaces of the substrate, the device, and the sealant that form the cavity and the plurality of electrical interconnects, to repel the coolant liquid and contaminants away from the plurality of electrical interconnects. The oleophobic coating may include a cross-linked fluoropolymer. The oleophobic coating may include at least one of 3M™ Novec™ 2708 or 3M™ EGC-2788. The sealant may be a first sealant and the computing system may further include a second sealant disposed directly onto the first sealant. The first sealant and the second sealant may have identical material compositions. The first sealant and the second sealant may have different material compositions. The computing system may further include a protective coating, disposed directly onto the sealant, to suppress boiling of the coolant liquid and repel the coolant liquid and contaminants away from the sealant. The protective coating may include at least one of 3M™ Novec™ 2708, 3M™ EGC-2788, or HumiSeal® 1B73.

The system may further include the coolant liquid disposed in the tank volume of the tank such that the computing system is submerged in the coolant liquid, and the one or more bubbles disposed in the cavity of the computing system. The one or more bubbles may include at least one of air or coolant vapor. The device may include at least one of a computer processor unit (CPU), a graphics processor unit (GPU), a data processing unit (DPU), a field-programmable gate array (FPGA), an application-specific integrated circuit (ASIC), or memory. The plurality of electrical interconnects may include a ball grid array (BGA). The substrate may include at least one of a printed circuit board (PCB) or a printed circuit board assembly (PCBA).

In another example implementation, a system comprises a two-phase immersion cooling system comprising a tank defining a tank volume configured to contain a coolant liquid, and a computing system disposed within the tank volume and configured to be submerged in the coolant liquid where the computing system comprises a substrate, a device including an integrated circuit, a plurality of electrical interconnects to electrically couple the device to the substrate, and an underfill disposed between the device and the substrate, wherein the underfill surrounds the plurality of electrical interconnects, and the underfill is configured to prevent the coolant liquid from physically contacting the plurality of electrical interconnects when the computing system is submerged in the coolant liquid.

The system may further include the coolant liquid disposed in the tank volume of the tank such that the computing system is submerged in the coolant liquid. The underfill may include at least one of 3M Scotch-Weld DP420, Zymet UA-2605-B, or Zymet X2821. The computing system may further include a sealant applied to the substrate and the device and disposed along at least a portion of each edge of the device. The sealant may include at least one of 3M™ Scotch-Weld DP420, Zymet X2821, Zymet UA-2605-B, Zymet UVE-1017-2, Zymet CN-1780-5, Zymet X2824, or Zymet UA-2701. The computing system may further include a protective coating, disposed onto at least a portion of the computing system, to suppress boiling of the coolant liquid and repel the coolant liquid and contaminants away from that portion of the computing system. The protective coating includes at least one of 3M™ Novec™ 2708, 3M™ EGC-2788, or HumiSeal® 1B73.

In yet another example implementation, a system comprises a two-phase immersion cooling system comprising a tank defining a tank volume configured to contain a coolant liquid, and a computing system disposed within the tank volume and configured to be submerged in the coolant liquid where the computing system comprises a substrate, a device including an integrated circuit, a plurality of electrical interconnects to electrically couple the device to the substrate, and a protective coating, disposed onto the plurality of electrical interconnects, to suppress boiling of the coolant liquid and repel the coolant liquid and contaminants away from the plurality of electrical interconnects.

The system may further include the coolant liquid disposed in the tank volume of the tank such that the computing system is submerged in the coolant liquid. The protective coating may further include at least one of 3M™ Novec™ 2708, 3M™ EGC-2788, or HumiSeal® 1B73.

In yet another example implementation, a computing system configured for immersion in a coolant liquid of a two-phase immersion cooling system comprises a substrate, a device, mounted to the substrate, having an integrated circuit, and a sealant directly coupled to the substrate and the device and disposed along at least a portion of each edge of the device such that the sealant, the device, and the substrate together form a cavity configured to trap one or more bubbles of a gas when the computing system is immersed in the coolant liquid.

The device may have a shape that is one of a rectangle or a square, when the computing system is submerged in the coolant liquid, the device may be oriented vertically and have a top edge, a right-side edge joined to the top edge, a bottom edge joined to the right-side edge, and a left-side edge joined to the bottom edge and the top edge, and the sealant may be disposed along all of the top edge, the left-side edge, and the right-side edge and only a portion of the bottom edge to provide at least one opening into the cavity along the bottom edge. The at least one opening may be a single opening having a width less than or equal to about 1 millimeter. The sealant may cover all edges of the device. The sealant may be disposed around respective edges of the device such that an opening is formed into the cavity, and the computing system may further include a plug disposed in the opening to seal the opening. The sealant may be a first sealant, and the computing system may further include a second sealant partially disposed onto the first sealant and directly coupled to the substrate and the device. The sealant may include at least one of a two-part epoxy, or an ultraviolet curable epoxy. The computing system may further include an oleophobic coating disposed on respective surfaces of the substrate, the device, and the sealant that form the cavity. The oleophobic coating may include a cross-linked fluoropolymer.

The computing system may be incorporated into a system that includes a two-phase immersion cooling system with a tank defining a tank volume, coolant liquid disposed within the tank volume, and a heat exchanger partially disposed in the tank volume above the coolant liquid. The computing system may be submerged in the coolant liquid within the tank volume such that during operation of the system, one or more bubbles of a gas are trapped in the cavity of the computing system. The gas may be at least one of coolant vapor or air. The device may be mounted to the substrate via a ball grid array.

In yet another example implementation, a computing system configured for immersion in a coolant liquid of a two-phase immersion cooling system comprises a substrate, a device, mounted to the substrate, having an integrated circuit, an extension plate, coupled to the device and extending from at least one edge of the device over the substrate, and a sealant directly coupled to the substrate and the extension plate and disposed along at least a portion of each edge of the extension plate such that the sealant, the extension plate, the device, and the substrate together form a cavity configured to trap one or more bubbles of a gas when the computing system is immersed in the coolant liquid.

In yet another example implementation, a computing system configured for immersion in a coolant liquid of a two-phase immersion cooling system comprises a substrate, a device, mounted to the substrate, having an integrated circuit, a boiler plate, coupled to the device and extending from at least one edge of the device over the substrate where the boiler plate has a boiling enhancement coating to promote boiling of the coolant liquid, and a sealant directly coupled to the substrate and the boiler plate and disposed along at least a portion of each edge of the boiler plate such that the sealant, the boiler plate, the device, and the substrate together form a cavity configured to trap one or more bubbles of a gas when the computing system is submerged in the coolant liquid.

In yet another example implementation, a computing system configured for immersion in a coolant liquid of a two-phase immersion cooling system comprises a substrate, a device, mounted to the substrate, having an integrated circuit, a boiler plate, coupled to the device, having a boiling enhancement coating to promote boiling of the coolant liquid, a retention plate, coupled to the boiler plate, to securely couple the boiler plate and the device to the substrate, and a sealant directly coupled to the substrate and the retention plate and disposed along at least a portion of each edge of the retention plate such that the sealant, the retention plate, the boiler plate, the device, and the substrate together form a cavity configured to trap one or more bubbles of a gas when the computing system is submerged in the coolant liquid.

In yet another example implementation, a computing system comprises a substrate and a device having an integrated circuit. A method for assembling the computing system for installation into a two-phase immersion cooling system comprises: A) mounting the device to the substrate; B) applying a sealant along at least a portion of each edge of the device such that the sealant, the device, and the substrate together forms a cavity configured to trap one or more bubbles of a gas when the computing system is immersed in the coolant liquid and at least one opening into the cavity is formed; C) inserting a fluoropolymer solution into the cavity through the at least one opening to coat respective surfaces of the substrate, the device, and the sealant that form the cavity; and D) heating the computing system to a temperature of about 120° C. to cure the fluoropolymer coating.

The device may have a shape that is one of a rectangle or a square with a first edge, a second edge may be joined to the first edge, a third edge may be joined to the second edge, and a fourth edge may be joined to the third edge and the first edge, and applying the sealant along at least a portion of each edge of the device may include applying the sealant along all of the first edge, the second edge, and the third edge and only a portion of the fourth edge to provide the at least one opening along the fourth edge. The method may further include submerging the computing system into coolant liquid of a two-phase immersion cooling system such that the device is oriented vertically with the first edge being a left-side edge, the second edge being a top edge, the third edge being a right-side edge, and the fourth edge being a bottom edge. The step of inserting the fluoropolymer solution into the cavity may include injecting, via a syringe, the fluoropolymer solution into the cavity through the at least one opening. The step of inserting the fluoropolymer solution into the cavity may include dipping the computing system into a bath of fluoropolymer solution where the fluoropolymer solution enters the cavity through the at least one opening.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIG. 1A shows a side view of a computing system with a device mounted to a substrate via a ball grid array (BGA).

FIG. 1B shows a side view of the computing system of FIG. 1A immersed in coolant liquid with oil contamination.

FIG. 1C shows a cross-sectional view of the computing system of FIG. 1A immersed in coolant liquid corresponding to the plane A-A in FIG. 1A.

FIG. 1D shows a cross-sectional view of the computing system of FIG. 1A corresponding to the plane A-A in FIG. 1A after oil contamination has accumulated.

FIG. 2A shows a diagram depicting the relative proportion of material constituents in a solder flux before and after soldering.

FIG. 2B shows a solder joint with soldering residue originating from solder flux.

FIG. 2C shows the solder joint of FIG. 2B where activators contained in the soldering residue are exposed due to accelerated aging of the soldering residue.

FIG. 2D shows a photograph of an aged soldering residue surrounding a solder ball in a BGA.

FIG. 2E shows a photograph of multiple solder balls in the BGA of FIG. 2D with distilled oil deposited thereon.

FIG. 2F shows a photograph of an example BGA with pristine soldering residue surrounding solder balls of the BGA.

FIG. 3A shows a side view of a portion of an example two-phase immersion cooling system that includes a computing system with a device mounted to a substrate and sealant applied to a portion of the edges of the device such that an opening on the bottom side of the device is formed.

FIG. 3B shows a bottom view of the device of FIG. 3A with vapor trapped in the cavity between the ball grid array, the edge bond, and the PCB.

FIG. 4A shows a side view of an example computing system with a device mounted to a substrate and a sealant applied to a portion of the edges of the device such that an opening is formed.

FIG. 4B shows a bottom view of the computing system of FIG. 4A.

FIG. 4C shows a cross-sectional view of the computing system of FIG. 4A according to the plane A-A in FIG. 4A.

FIG. 5 shows an example two-phase immersion cooling system and the computing system of FIG. 4A installed into the two-phase immersion cooling system.

FIG. 6A shows a side view of another example computing system with a device mounted to a substrate, a sealant applied to a portion of the edges of the device such that an opening is formed, and an oleophobic coating applied to the device, the substrate, and the sealant.

FIG. 6B shows a cross-sectional view of the computing system of FIG. 6A according to the plane A-A in FIG. 6A.

FIG. 7A shows a side view of another example computing system with a device mounted to a substrate, an extension plate mounted to the device, and a sealant applied to a portion of the edges of the extension plate such that an opening is formed.

FIG. 7B shows a cross-sectional view of the computing system of FIG. 7A according to the plane A-A in FIG. 7A.

FIG. 7C shows a cross-sectional view of the computing system of FIG. 7A according to the plane B-B in FIG. 7A.

FIG. 7D shows a side view of another example computing system with a device mounted to a substrate and a sealant applied to a portion of the edges of the device such that an opening is formed. A gap is also formed near the opening to separate the sealant from electrical interconnects near the opening.

FIG. 8 shows a side view of another example computing system with a device mounted to a substrate and a sealant applied to all the edges of the device.

FIG. 9A shows a side view of another example computing system with a device mounted to a substrate and a sealant applied to a portion of the edges of the device, and a plug inserted into an opening formed by the sealant.

FIG. 9B shows a bottom view of the computing system of FIG. 9A.

FIG. 9C shows another side view of the computing system of FIG. 9B where the plug is removed due, for example, to an increase in pressure within a cavity formed by the device, the substrate, and the sealant.

FIG. 10A shows a side view of another example computing system with a device mounted to a substrate and two layers of sealant applied to the edges of the device.

FIG. 10B shows a cross-sectional view of the computing system of FIG. 10A according to the plane A-A in FIG. 10A.

FIG. 11A shows a side view of another example computing system with a device mounted to a substrate, sealant applied to the edges of the device, and an underfill between the device and the substrate.

FIG. 11B shows a cross-sectional view of the computing system of FIG. 11A according to the plane A-A in FIG. 11A.

FIG. 12 shows a cross-sectional view of another example computing system with a device mounted to a substrate, a boiler plate coupled to the device, and a sealant applied to the edges of the boiler plate.

FIG. 13 shows a cross-sectional view of another example computing system with a device mounted to a substrate, a boiler plate coupled to the device, a retention plate to securely mount the boiler plate and the device to the substrate, and a sealant applied to the edges of the retention plate.

FIG. 14 shows a flow chart for an example method of assembling a computing system with a sealant for installation into a two-phase immersion cooling system.

FIG. 15 shows a table of example materials that may be used as a sealant or as an underfill.

FIG. 16A shows a cross-sectional view of an example device of a computing system with a sealant applied to the edges of the device.

FIG. 16B shows a side view of a computing system where the sealant is applied to edges of the device in one pass such that an opening/vent is formed.

FIG. 16C shows a side view of a computing system where the sealant is applied to all edges of the device in one pass.

FIG. 16D shows a side view of a computing system where a first sealant is applied to edges of the device in one pass such that an opening/vent is formed and a second sealant is applied to fill the opening/vent thereafter.

FIG. 17 shows a BGA-mounted device with underfill which prevents boiling from occurring within the BGA region.

FIG. 18 shows an example surface mounted field effect transistor (FET) with a coating applied on and near the solder leads.

FIG. 19 shows an example through-hole FET with a coating applied to exposed portions of the leads.

FIG. 20 shows an example chip carrier with a ball grid array (BGA) and a coating applied to the BGA.

FIG. 21 shows example electrical pins connecting multiple circuit boards together with coatings applied to the pins and the circuit boards.

FIG. 22A shows a photograph of example electronic devices with a BGA and underfill.

FIG. 22B shows another photograph of example electronic devices with a BGA and underfill.

FIG. 22C shows a photograph of example electronic devices with a coating.

FIG. 23 shows an example GPU server.

FIG. 24 shows a table of material properties for 3M™ Novec™ 2708.

FIG. 25 shows a table of material properties for 3M™ Scotch-Weld DP420.

FIG. 26 shows a table of material properties for Zymet X2821.

FIG. 27 shows a table of material properties for Zymet UA-2605-B.

FIG. 28 shows a table of material properties for Zymet CN-1780-5.

FIG. 29 shows a table of material properties for Humiseal® 1B73.

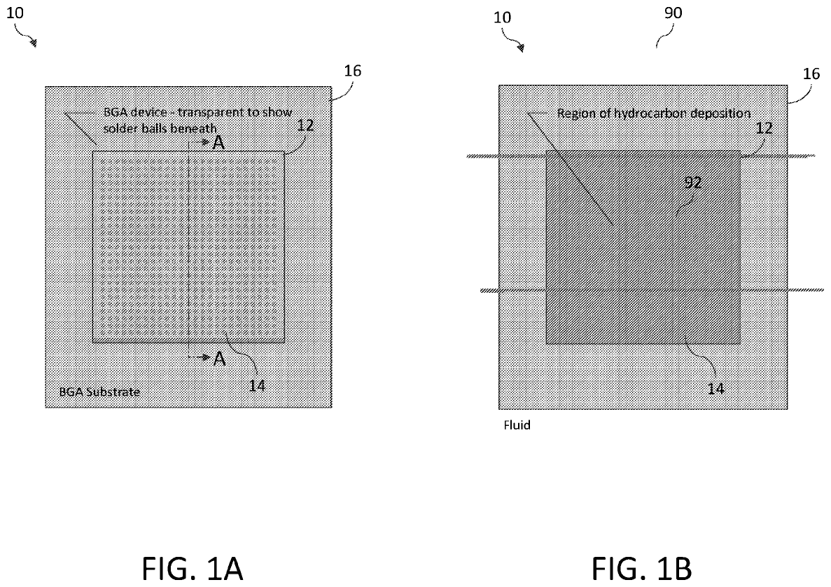

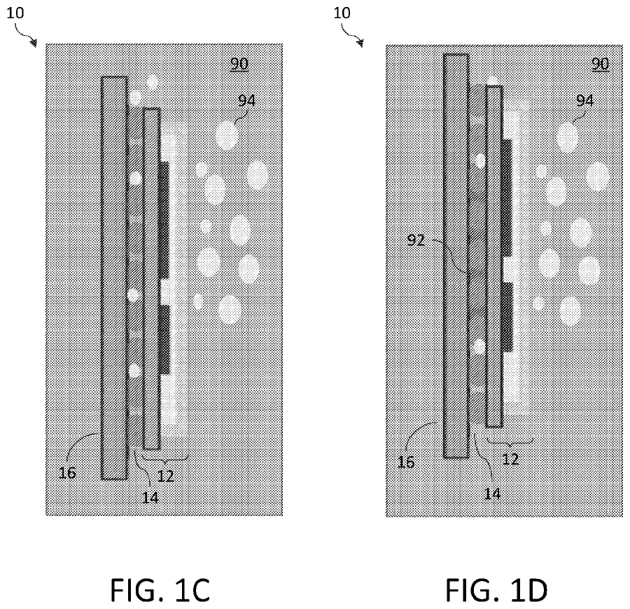

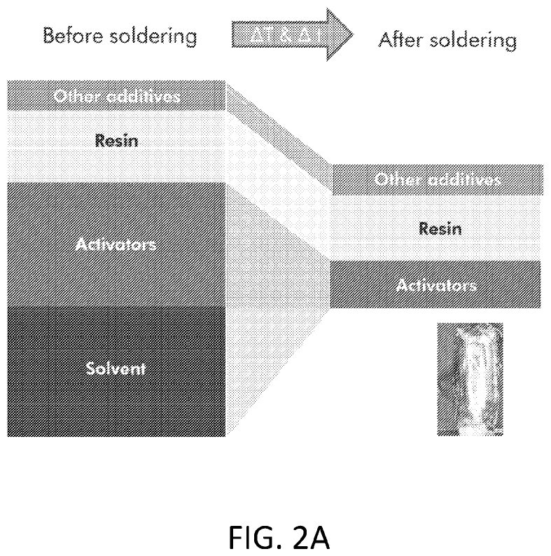

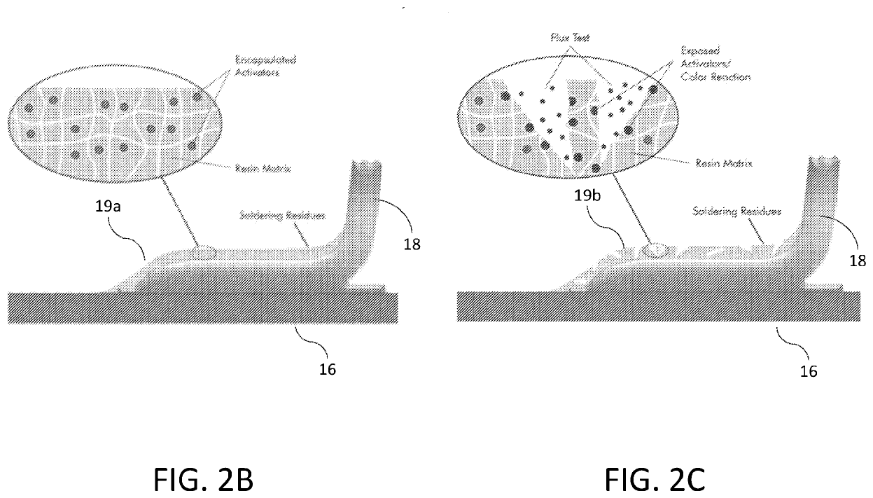

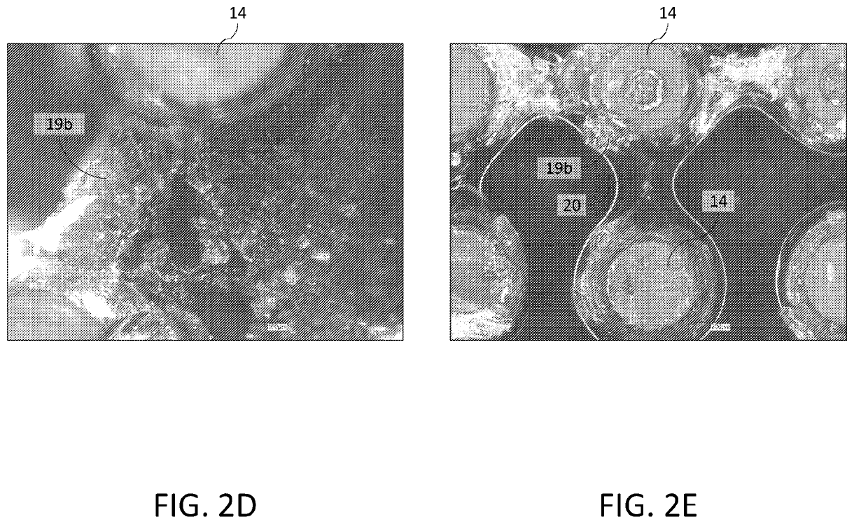

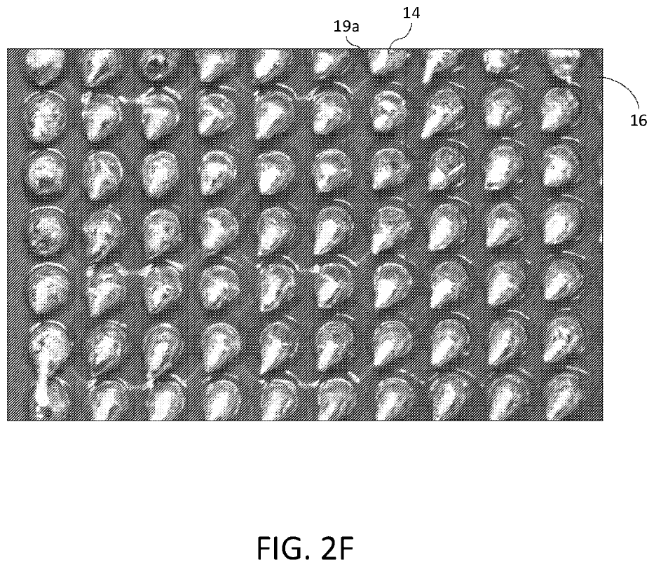

### DETAILED DESCRIPTION

Following below are more detailed descriptions of various concepts related to, and implementations of, a protected electronic device configured for immersion in a coolant liquid of a two-phase immersion cooling system, which reduces or, in some instances, prevents deposition of undesirable contaminants between the device and a substrate-particularly on electrical interconnects disposed between the device and the substrate. The device may be protected from the coolant liquid in several ways including, but not limited to, an edge bond, an underfill, a protective coating, or any combinations of the foregoing. The present disclosure is also directed to computing systems that include the electronic devices disclosed herein and methods for assembling the computing system. It should be appreciated that various concepts introduced above and discussed in greater detail below may be implemented in multiple ways. Examples of specific implementations and applications are provided primarily for illustrative purposes so as to enable those skilled in the art to practice the implementations and alternatives apparent to those skilled in the art.

The figures and example implementations described below are not meant to limit the scope of the present implementations to a single embodiment. Other implementations are possible by way of interchange of some or all of the described or illustrated elements. Moreover, where certain elements of the disclosed example implementations may be partially or fully implemented using known components, in some instances only those portions of such known components that are necessary for an understanding of the present implementations are described, and detailed descriptions of other portions of such known components are omitted so as not to obscure the present implementations.

In the discussion below, various examples of a protected electronic device and computing systems including one or more of the protected electronic devices are provided, wherein a given example or set of examples showcases a sealant, an oleophobic coating, an underfill, and a protective coating. Various properties of the sealant, the oleophobic coating, the underfill, and the protective coating are also discussed including, but not limited to, resistivity, dielectric constant, dielectric strength, coefficient of thermal expansion, surface roughness, hydrophobicity, oleophobicity, and material composition. It should be appreciated that one or more features discussed in connection with a given example of a protected electronic device or computing system may be employed in other examples of protected electronic devices and computing systems, respectively, according to the present disclosure, such that the various features disclosed herein may be readily combined in a given protected electronic device or computing system according to the present disclosure (provided that respective features are not mutually inconsistent).

Certain dimensions and features of the protected electronic devices and/or the computing systems are described herein using the terms “approximately,” “about,” “substantially,” and/or “similar.” As used herein, the terms “approximately,” “about,” “substantially,” and/or “similar” indicates that each of the described dimensions or features is not a strict boundary or parameter and does not exclude functionally similar variations therefrom. Unless context or the description indicates otherwise, the use of the terms “approximately,” “about,” “substantially,” and/or “similar” in connection with a numerical parameter indicates that the numerical parameter includes variations that, using mathematical and industrial principles accepted in the art (e.g., rounding, measurement or other systematic errors, manufacturing tolerances, etc.), would not vary the least significant digit.

### 1. Examples of Edge Sealed Electronic Devices

One example approach to protect electronic devices from exposure to a coolant liquid in an immersion cooling system (e.g., a two-phase immersion cooling system) is to seal at least a portion of the edges of the device. In this manner, the underlying electrical interconnects that electrically couple the device to a substrate (e.g., a PCB) may be less exposed to the coolant liquid and, thus, less prone to accumulating contaminants from the coolant liquid during operation. Following below are several example implementations of edge sealed electronic devices that utilize a sealant to form an edge bond around the sides of the device.

### 1.1 An Example Three-sided Edge Bond

A surface-mounted device, such as a powerVR, is typically mounted to a substrate (e.g., a PCB, PCBA) via a ball grid array (BGA), which generates a significant heat flux in a coolant liquid. This heat flux is sufficient to cause underside boiling and, thus, the accumulation of contaminants and the formation of dendrites across the solder balls, which may lead to shorting and premature device failure. These issues may be resolved by isolating the surface-mounted device with an edge bond disposed around at least two sides, preferably three sides, and even more preferably four sides of the surface-mounted device with an opening to capture and trap bubbles (e.g., a vapor bubble produced from underside boiling). The opening is located in at least a portion of the side that is orthogonal to the direction of gravity. The bubble is trapped within the cavity formed between the surface-mounted device, the PCB, and the edge bond. The trapped bubble may prevent further infiltration of coolant liquid and, thus contaminants from entering the cavity formed under the surface-mounted device and, hence, remain as a vapor bubble. The bubble also changes the signal integrity characteristics by reducing or eliminating the dielectric fluid under the surface-mounted device and allowing the electromagnetic fields to better propagate and thereby improve the signal performances in that space.

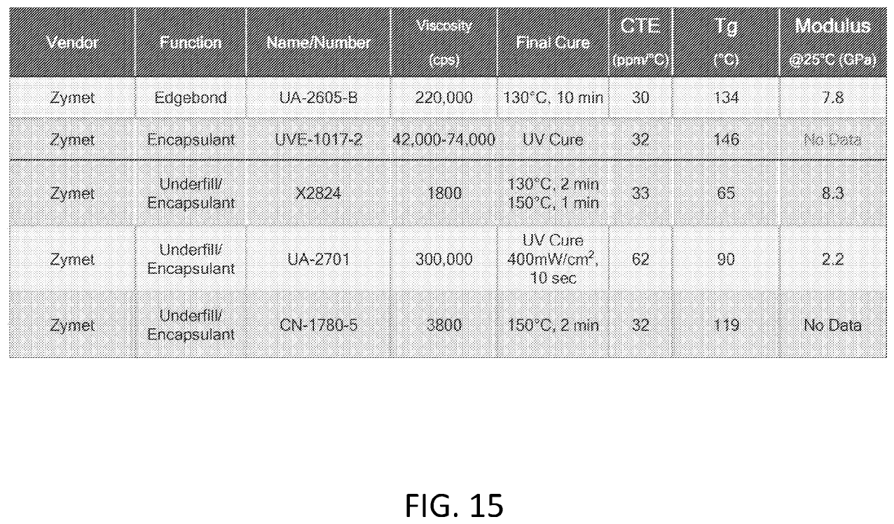

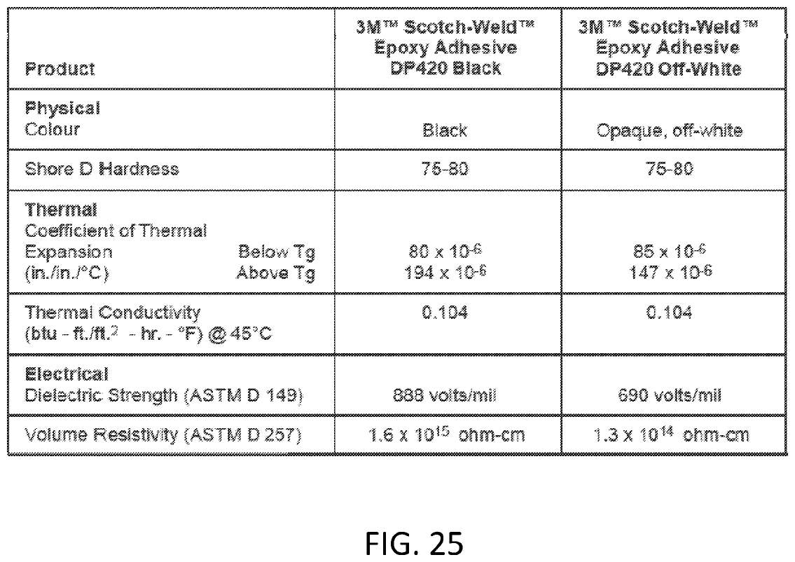

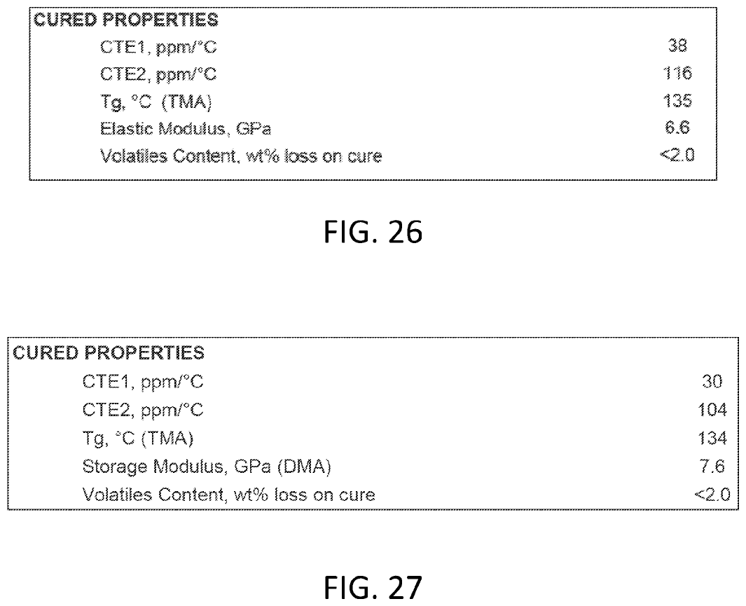

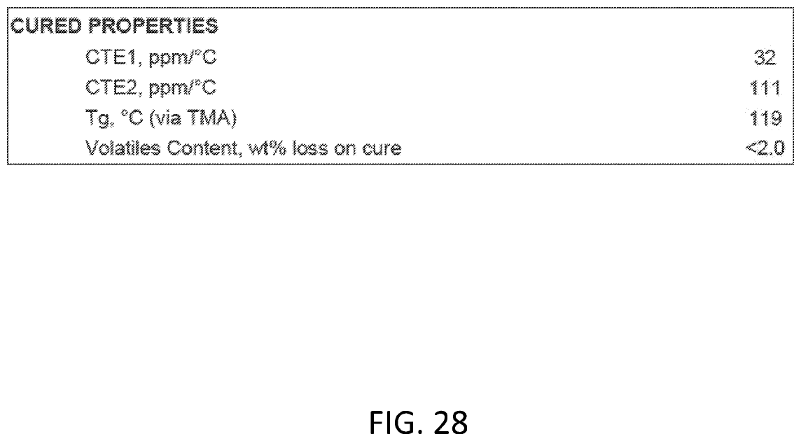

The edge bond may be formed using a sealant comprising a compound that hardens (e.g., a two-part epoxy, UV epoxy, composite, or eutectic metal). Non-limiting examples of suitable sealants include, but are not limited to, 3M™ Scotch-Weld DP420, Zymet X2821, Zymet UA-2605-B, Zymet UVE-1017-2, Zymet CN-1780-5, Zymet X2824, and Zymet UA-2701. Preferably, the sealant has a resistivity, dielectric constant, dielectric strength, and coefficients of thermal expansion within 25%, preferably within 5% to 10%, of one or both of 3M™ Scotch-Weld DP420, Zymet X2821, Zymet UA-2605-B, Zymet UVE-1017-2, Zymet CN-1780-5, Zymet X2824, and/or Zymet UA-2701. For reference, FIG. 25 provides a table of material properties for 3M™ Scotch-Weld DP420, FIG. 26 provides a table of material properties for Zymet X2821, FIG. 27 provides a table of material properties for Zymet UA-2605-B, and FIG. 28 provides a table of material properties for Zymet CN-1780-5. In one example, Zymet UVE-1017-2 has a coefficient of thermal expansion of about 17.5 ppm/° C. FIG. 15 further provides material properties for some of the foregoing materials.

The dielectric constant of the sealant may be less than the dielectric constant of the coolant liquid. The dielectric constant of the sealant may be less than 1.8, such as 1.7, or 1.6, or 1.5, or 1.4, or 1.3 or less.

The surface-mounted device may include, but is not limited to, a power VR or a device with a BGA. The edge bond may encapsulate some or all of the electrical leads (e.g., solder ball) on each side of the surface-mounted device on which the edge bond is disposed, while leaving exposed the electrical leads within the cavity and on the side of the opening that permits vapor to enter the cavity.

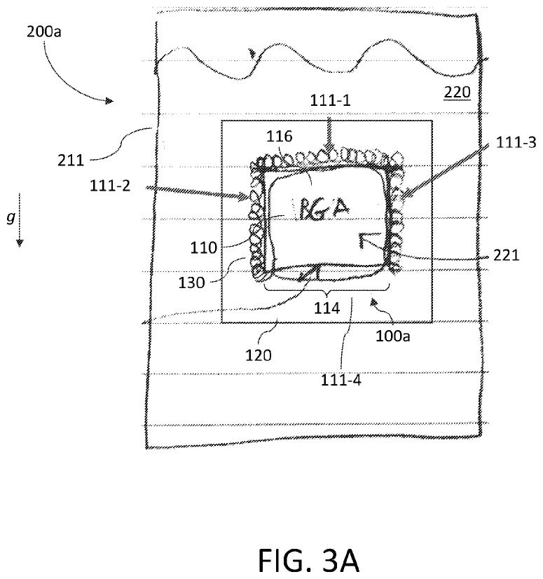

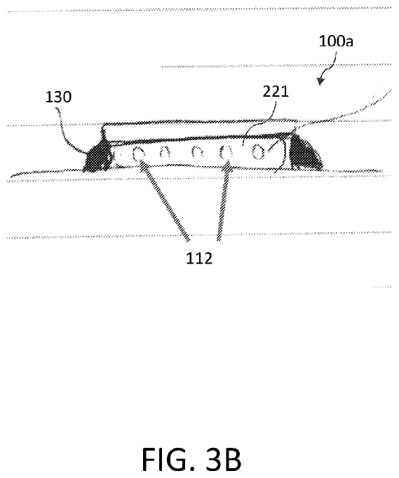

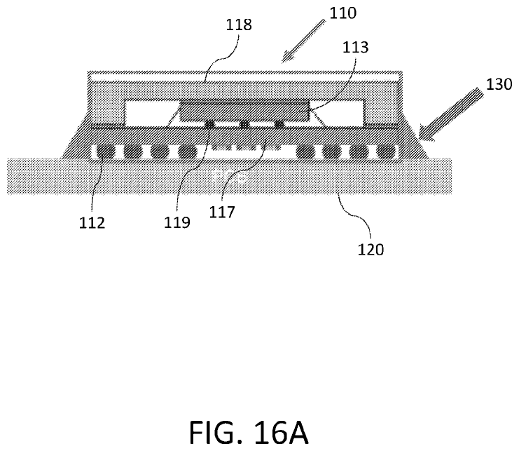

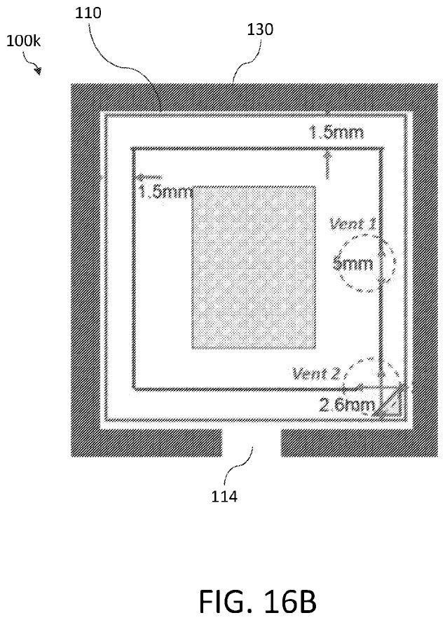

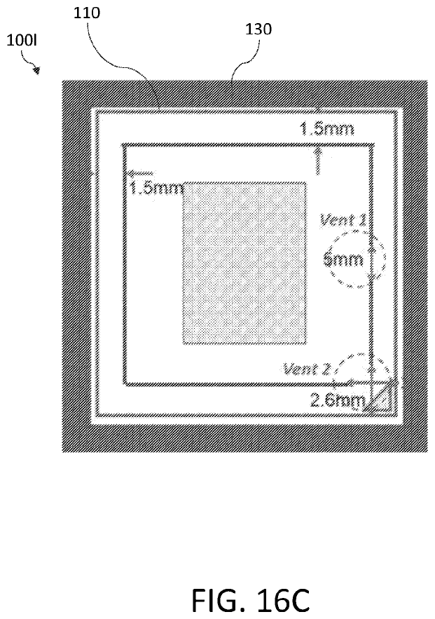

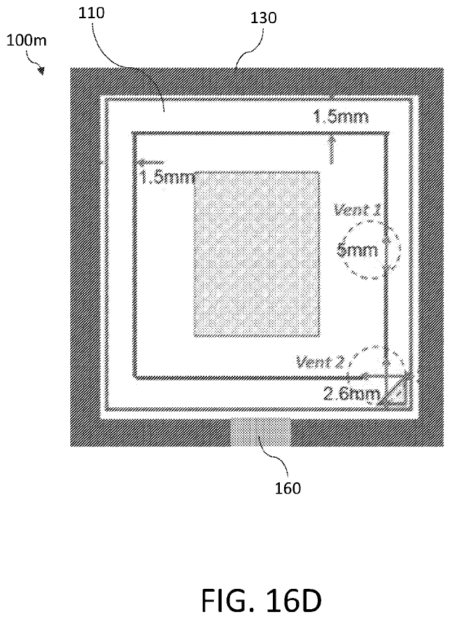

FIG. 3A shows a side view of a portion of an immersion cooling system 200a in which a computing system 100a with a BGA device 110 (referred to hereafter as a “device 110”) is mounted to a substrate 120 (e.g., a PCB) immersed in coolant liquid 220. The computing system 100 and the coolant liquid 220 are disposed within a tank 211 of the immersion cooling system 200a. Herein, it should be appreciated the device 110 may include an assembly of components including, but not limited to, a chip, a substrate (e.g., an interposer), and a lid. For example, FIG. 16A shows a more detailed view of an example device 110. As shown, the device 110 includes a chip 113 mounted to a substrate 117 (e.g., an interposer) via multiple electrical interconnects 119 (e.g., a BGA). The device 110 further includes a lid 118 coupled to the substrate 117 such that the lid 118 and the substrate 117 together form an enclosure to contain the chip 113. The lid 118 may thus provide a protective barrier for the chip 113. Additionally, the lid 118 may be thermally conductive and in direct contact with the chip 113 to facilitate dissipation of heat generated by the chip 113 during operation.

A sealant 130 is applied to the edges 111-1, 111-2, and 111-3 of the device 110 to form an edge bond. Thus, the edge bond is formed on three sides of the BGA device 110 (seen from this view as the top side corresponding to the edge 111-1, the right side corresponding to the edge 111-3, and the left side corresponding to the edge 111-2 of the BGA device 110). In the embodiment shown in FIG. 3A, minimal-to-no edge bond is formed on the bottom side corresponding to the edge 111-4 of the BGA device 110; in this case, the bottom side 111-4 is orthogonal to the direction of gravity. Herein, when the device 110 is vertically oriented as shown in FIG. 3A, the edge 111-1 is also referred to as the top side, the edge 111-2 is also referred to as the left side, the edge 111-3 is also referred to as the right side, and the edge 114 is also referred to as the bottom side. The edge bond on the top side 111-1, right side 111-3, and left side 111-2 of the BGA device 110 forms a cavity 116 between the BGA device 110, the substrate 120, and the sealant 130. Vapor bubbles produced from underside boiling float upward, in the direction opposite the direction of gravity. A portion of the vapor 221 becomes trapped within the cavity 116 between the BGA device 110, the substrate 120, and the edge bond formed by the sealant 130.

FIG. 3B shows a bottom view of the system 100a shown in FIG. 3A, viewed from the perspective of vapor bubbles traveling up into the cavity 116. The trapped bubbles of vapor 221 are shown in the cavity 116 between the BGA device 110, the substrate 120, and the edge bond formed by the sealant 130. The cavity 116 includes electrical interconnects (e.g., solder balls 112 in FIG. 3B) some or all of which are not encapsulated by the edge bond and are not in contact with coolant liquid 220 but are instead surrounded and protected by the bubbles of vapor 221 within the cavity 116. The bubble(s) 221 within the cavity 116 prevents coolant liquid 220 from entering the cavity 116 and prevents the coolant liquid 220 from contacting the electrical interconnects (e.g., solder balls 112).

In FIGS. 3A and 3B, the edge bond is shown as being disposed along the entire respective lengths of the top side 111-1, right side 111-3, and left side 111-2 of the BGA device 110, with minimal-to-no edge bond disposed on the bottom side 111-4 of the BGA device 110. In some implementations, some sealant 130 may be disposed on the bottom side 111-4 of the BGA device 110, so long as a gap remains open on the bottom side (see, for example, the computing system 100b in Section 1.2). In some implementations, instead of the edge bond being disposed along the entire respective lengths of the right and left sides 111-3 and 111-2 of the BGA device 110, the sealant 130 may be disposed on a portion of the right and left sides 111-3 and 111-2 (e.g., the upper 25%-90% of the right and left sides 111-3 and 111-2). If the BGA device 110 is rotated 45° compared to its position in FIGS. 3A and 3B, then the sealant 130 forming the edge bond may instead be disposed on at least a portion of the two top-most sides of the BGA device 110 (e.g., the sides 111-1 and 111-2), and no edge bond may be disposed on either the entirety or at least the lower 25%-90% of the two bottom-most sides of the BGA device 110 (e.g., the sides 111-3 and 111-4).

### 1.2 An Example Four-sided Edge Bond

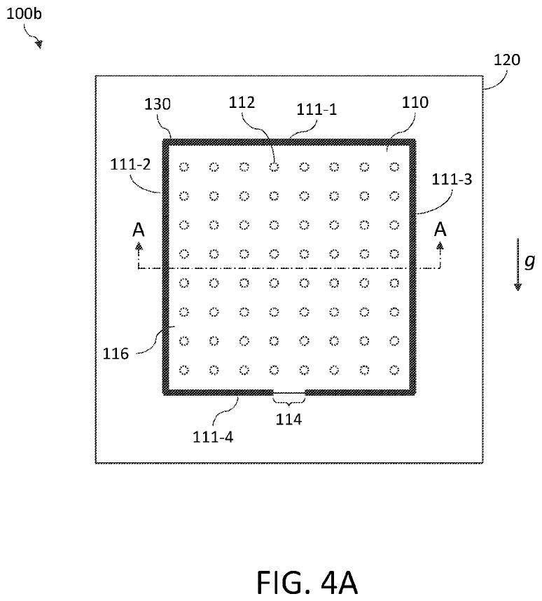

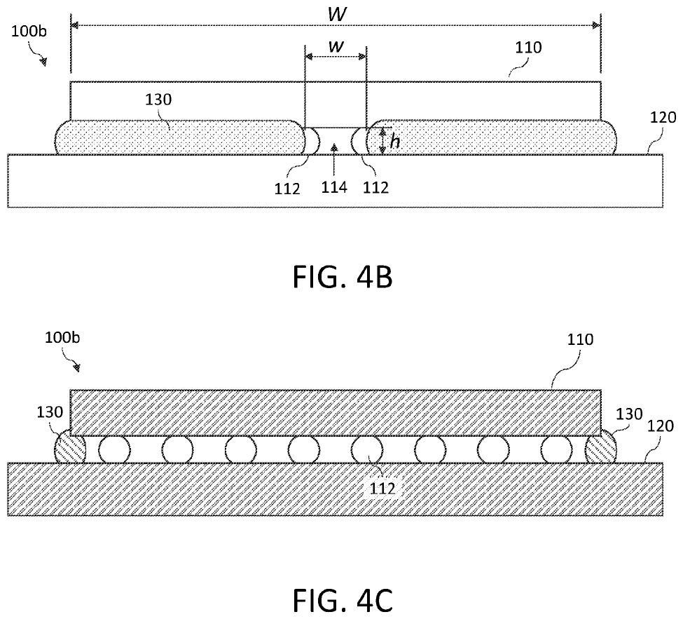

FIGS. 4A-4C show an example computing system 100b with an edge sealed electronic device 110 according to the inventive concepts disclosed herein. As shown, the device 110 is mounted to a substrate 120 via a ball grid array (BGA) 112. It should be appreciated that the computing system is a non-limiting example and that the edge sealed devices disclosed herein may be mounted to a substrate in other ways, such as with a pin grid array (PGA) or a land grid array (LGA). The device 110 may include an integrated circuit. For example, the device 110 may be a computer processor unit (CPU), a graphics processor unit (GPU), a data processing unit (DPU), a field-programmable gate array (FPGA), an application-specific integrated circuit (ASIC), memory (e.g., rapid access memory), and/or the like. The substrate 120 may be a printed circuit board (PCB) or a printed circuit board assembly (PCBA), e.g., a PCB with other electronic components mounted thereto.

As shown in FIG. 4A, the computing system 100b includes a sealant 130 disposed on the edges 111-1, 111-2, 111-3, and 111-4 of the device 110. The sealant 130 forms an edge bond that seals gaps formed between the device 110 and the substrate 120, thus preventing fluid from passing through the gaps between the device 110 and the substrate 120 where the sealant 130 is present. For example, FIG. 4C shows the sealant 130 may fill the gaps between the device 110 and the substrate 120 along the edges 111-2 and 111-3.

The sealant 130 may substantially cover the edges 111-1, 111-2, 111-3, and 111-4 such that the device 110, the substrate 120, and the sealant 130 together form a cavity 116 sufficient to trap one or more bubbles of a gas (e.g., coolant vapor, air). The bubble(s) trapped within the cavity 116 may reduce or, in some instances, prevent coolant liquid from entering the cavity 116. In this manner, the exposure of the BGA 112 to coolant liquid may be appreciably reduced, which, in turn, reduces or, in some instances, prevents failures related to the deposition of contaminants in the coolant liquid. Moreover, the bubble(s) include air and/or coolant vapor, which has a dielectric constant similar to air. Thus, the bubble(s) of air and/or coolant vapor in the cavity 116 may provide a more desirable characteristic impedance for the BGA 112 compared to when the BGA 112 is submerged in coolant liquid, thus improving signal integrity.

For the example computing system 100b, FIG. 4A shows the sealant 130 may cover the entirety of the edges 111-1, 111-2, and 111-3 and only a portion of the edge 111-4 such that an opening 114 is formed. The opening 114 provides a way to relieve any buildup of pressure within the cavity 116. In some implementations, the computing system 100b may be oriented such that the edges 111-2 and 111-3 are oriented vertically and the edges 111-1 and 111-4 are oriented horizontally with the edge 111-1 disposed above the edge 111-4, as shown in FIG. 4A (the vector g represents the direction of gravity). Thus, the edges 111-1, 111-2, 111-3, and 111-4 may correspond to a top edge, left-side edge (or, alternatively, a right-side edge), a right-side edge (or, alternatively, a left-side edge), and a bottom edge, respectively, and the opening 114 may be disposed towards the bottom of the device 110. This orientation may allow bubbles generated below the device 110 to enter the cavity 116 the opening 114. Additionally, coolant liquid and/or excess gas may be vented out of the cavity 116 while still trapping bubble(s) of the gas.

FIG. 4B shows the opening 114 may be centered along the edge 111-4 and have a width, w. In some implementations, the width w may be less than or equal to about 5 millimeters (mm), including all values and sub-ranges in between. In some implementations, the width w may be less than or equal to about 2 mm, including all values and sub-ranges in between. In some implementations, the width w may be less than or equal to about 1 mm, including all values and sub-ranges in between. In some implementations, the width w may be less than or equal to about 100 microns, including all values and sub-ranges in between. The width, w, of the opening 114 may be defined relative to the overall width, W, of the device 110. In some implementations, the width, w, may be less than or equal to about 10% of the overall width, W. In some implementations, the width, w, may be less than or equal to about 1% of the overall width, W. The opening 114 may further have a height, h, as shown in FIG. 4B. The height, h, generally depends on the size of the electrical interconnects (e.g., the BGA 112). In some implementations, the height, h, may be less than or equal to about 10 mm, including all values and sub-ranges in between. In some implementations, the height, h, may be less than or equal to about 5 mm, including all values and sub-ranges in between. In some implementations, the height, h, may be less than or equal to about 2 mm, including all values and sub-ranges in between. It should be appreciated that the height of the edge bond formed by the sealant 130 is greater than the height, h, of the opening 114. Each of the edges 111-1, 111-2, 111-3, and 111-4 may have a length that ranges from about 20 mm to about 50 mm, including all values and sub-ranges in between. In some implementations, the edges 111-1, 111-2, 111-3, and 111-4 may have a length that ranges from about 30 mm to about 36 mm, including all values and sub-ranges in between. The term “about,” when used to describe the width, w, of the opening 114, is intended to cover variations that may arise when the sealant 130 is applied. For example, “about 1 mm” may correspond to the following dimensional ranges: 0.99 mm to 1.01 mm (+/−1% variation), 0.98 mm to 1.02 mm (+/−2% variation), 0.97 mm to 1.03 mm (+/−3% variation), 0.96 mm to 1.04 mm (+/−4% variation), 0.95 mm to 1.05 mm (+/−5% variation), including all values and sub-ranges in between.

It should be appreciated that the opening 114 in the computing system 100b is a non-limiting example. In other examples, the opening 114 may be positioned at any location along the edge 111-4. In some implementations, the opening 114 may be formed on the edge 111-2, the edge 111-3, or at the corner between the edges 111-2 and 111-4 or the edges 111-3 and 111-4. For example, the opening 114 may be formed towards the bottom of the edge 111-2 or the edge 111-3 so that the bubble(s) of gas remain trapped in the cavity 116. In some implementations, multiple openings may be formed along the edge bond. For example, two or more openings may be formed along the edge 111-4. The multiple openings may be evenly distributed along the bottom edge 111-4.

It should also be appreciated that the orientation of the computing system 100 and/or the device 110 described above (e.g., with the edges 111-1 and 111-4 oriented horizontally and the edges 111-2 and 111-3 oriented vertically) is a non-limiting example. More generally, the computing system 100 and/or the device 110 may be oriented in any arbitrary direction. Accordingly, the sealant 130 may be applied such that the opening 114 is formed towards the bottom of the device 110. For example, if the device 110 is rotated 45 degrees clockwise with respect to the orientation shown in FIG. 4A and the vector g remains unchanged, the edges 111-3 and 111-4 would be disposed towards the bottom of the device 110 and the edges 111-1 and 111-2 would be disposed towards the top of the device 110. The opening 114 may thus be located at the corner formed by the edges 111-3 and 111-4.

It should also be appreciated that the sealant 130 may be applied to devices of various shapes. For example, the device 110 may generally be substantially flat and have a shape that includes, but is not limited to, a square, a rectangle, a circle, a polygon, and any combinations of the foregoing. Additionally, the device 110 may have beveled or rounded corners.

The sealant 130 may be formed from a compound that hardens (e.g., a UV epoxy, a composite, or a eutectic metal), as described above in Section 1.1. Non-limiting examples of suitable sealants 130 include, but are not limited to, 3M™ Scotch-Weld DP420, Zymet X2821, Zymet UA-2605-B, Zymet UVE-1017-2, Zymet CN-1780-5, Zymet X2824, and Zymet UA-2701. Preferably, the sealant 130 has a resistivity, dielectric constant, dielectric strength, and coefficients of thermal expansion within 25%, preferably within 5% to 10%, of one or both of 3M™ Scotch-Weld DP420, Zymet X2821, Zymet UA-2605-B, Zymet UVE-1017-2, Zymet CN-1780-5, Zymet X2824, and/or Zymet UA-2701.

The sealant 130 may generally be applied after the device 110 is mounted to the substrate 120. After application, the sealant 130 may be cured, for example, by heating the sealant 130 to an elevated temperature, exposing the sealant 130 to radiation (e.g., ultraviolet radiation), and/or waiting for a predetermined period of time for the sealant 130 to harden. In one example, FIG. 16B shows an example computing system 100k where a sealant 130 (e.g., Zymet UA-2605-B) is applied in one pass around the edges of the device 110 such that an opening (e.g., vent) 114 is formed. The opening 114 may have a width less than 2 millimeters. Thereafter, the sealant 130 is thermally cured at a temperature of 130° C. for 10 minutes.

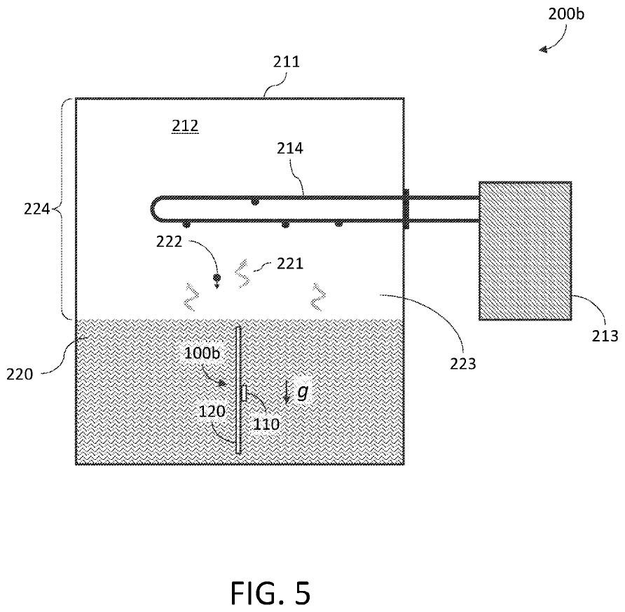

FIG. 5 shows an example two-phase immersion cooling system 200b that includes the computing system 100b of FIG. 4A. As shown, the system 200b includes a tank 211 defining a tank volume 212 to contain coolant liquid 220. The computing system 100b is shown submerged in the coolant liquid 220. The system 200b further includes a cooling distribution unit 213 with a heat exchanger (e.g., a condenser coil 214) that carries a secondary coolant. The condenser coil 214 is partially disposed in the tank volume 212 above the coolant liquid 220.

During operation, the device 110 generates heat, which may be dissipated to the coolant liquid. When the coolant liquid is sufficiently heated, the coolant liquid vaporizes producing coolant vapor 221, which rises above into a gas space 224 within the tank volume 212 containing a mixture 223 of air and coolant vapor. As the coolant vapor 221 physically contacts the condenser coil 214, heat from the coolant vapor 221 is transferred to the secondary coolant carried by the condenser coil 214, thus causing the coolant vapor 221 to condense to liquid droplets 222 that falls back into the coolant liquid 220 below. The secondary coolant is circulated to the cooling distribution unit 213 where the heat is thereafter dissipated from the secondary coolant.

One or more bubbles of the gas may be trapped in the cavity 116 during operation of the computing system 100b. The bubbles of gas may be provided in several ways. For example, bubbles of air may be initially trapped in the cavity 116 when immersing the computing system 100b into the coolant liquid 220. In another example, bubbles of coolant vapor 221 and/or air may flow into the cavity 116 from other electronic components and/or devices (not shown) disposed below the device 110. In yet another example, the heat generated by the BGA 112 between the device 110 and the substrate 120 may boil the coolant liquid 220 initially present in the cavity 116. The resultant coolant vapor 221 may, in turn, become trapped in the cavity 116 and either push out any remaining coolant liquid 220 within the cavity 116 through the opening 114 in the edge bond and/or prevent coolant liquid 220 outside the device 110 (e.g., in the tank volume 212) from entering the cavity 116.

### 1.3 An Example Edge Sealed Electronic Device With an Oleophobic Coating

The coolant liquids commonly used in two-phase immersion cooling systems often have low surface tension and thus readily wet various surfaces of the computing systems disclosed herein. In particular, the coolant liquid may infiltrate small crevices via wicking. The crevices may be formed, for example, between the sealant and the device and/or between the sealant and the substrate. Any contaminants (e.g., particulates, dissolved water, high molecular weight oils and/or other non-volatile residues) mixed with the coolant liquid may also be transported along these crevices. When the coolant liquid infiltrates these crevices, the coolant liquid may thereafter evaporate (e.g., due to heating by the electrical interconnects near the sealant), thus resulting in the deposition of contaminants along these crevices.

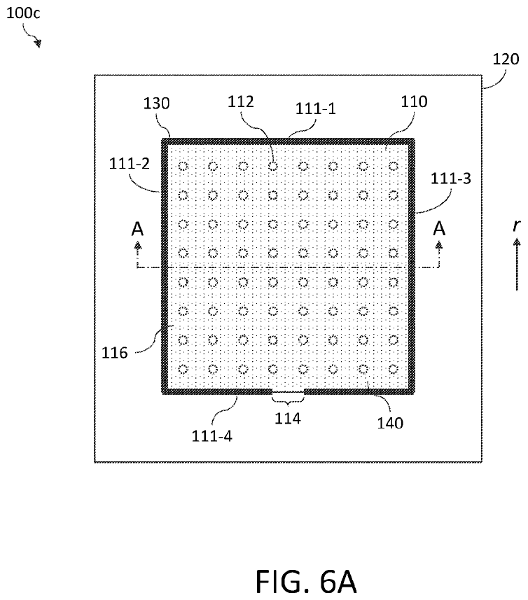

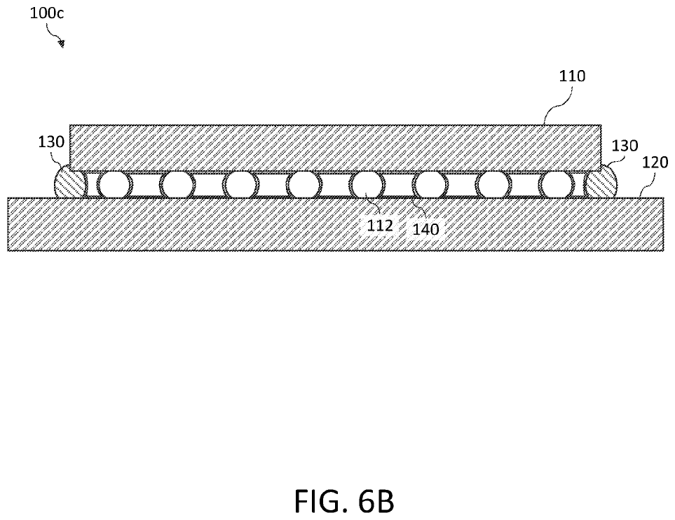

In some implementations, the crevices formed by the sealant may facilitate the infiltration of coolant liquid and, hence, the migration of contaminants into the cavity of the computing systems disclosed herein. To counteract this wetting behavior and repel the coolant liquid and the contaminants, an oleophobic coating may be applied to the interior surfaces of the cavity. For example, FIGS. 6A and 6B show a computing system 100c that includes an oleophobic coating 140 to reduce or, in some instances prevent infiltration of coolant liquid and contaminants into a cavity 116. The computing system 100c may include several of the same components and/or features as the computing system 100b. The computing system 100c may further operate in a similar manner to the computing system 100b, unless indicated otherwise. For brevity, repeated discussions of these features may not be provided below.

As shown in FIG. 6A, the computing system 100c may include a device 110 mounted to a substrate 120 via a ball grid array 112. A sealant 130 may further be applied to seal the gaps formed between the device 110 and the substrate 120 in the same manner as the computing system 100b. In particular, the sealant 130 may form an edge bond that covers the edges 111-1, 111-2, 111-3, and 111-4 of the device 110 except for an opening 114 formed on the edge 111-4.

The oleophobic coating 140 may be applied to the interior surfaces of the device 110, the substrate 120, and the sealant 130 that form the cavity 116. Additionally, the oleophobic coating 140 may be applied to the surfaces of any components disposed within the cavity 116, e.g., the BGA 112. In this manner, the surfaces within the cavity 116 may readily repel the coolant liquid and the contaminants, particularly near the opening 114. This, in turn, may appreciably reduce or, in some instances, prevent coolant liquid and contaminants from infiltrating the cavity 116.

It should also be appreciated that contaminants may be introduced into the cavity 116 during assembly of the computing system. For example, the computing system 100c may be cleaned before installation into an immersion cooling system. The cleaning process may entail using a chemical solvent, such as acetone or isopropyl alcohol. If the computing system is not adequately washed during the cleaning process, residues from the chemical solvents may remain on the surfaces of the computing system that form the cavity 116. These residues may, in turn, lead to undesirable electrochemical migration of metallic impurities and the formation of dendrites similar to the hydrocarbon contaminants described above.

Although it is preferable to remove these undesirable residues before the computing system is installed into an immersion cooling system, the complete removal of these residues may be too labor intensive and time consuming. The oleophobic coating 140 may thus provide another way to appreciably reduce or, in some instances, mitigate the adverse effects of undesirable residues introduced into the cavity 116 during assembly. In particular, the oleophobic coating 140 may coat the electrical interconnects in the cavity 116 (e.g., the BGA), thus forming a barrier that appreciably reduces or, in some instances, prevents interactions between the electrical interconnects and these residues. The oleophobic coating 140 may also directly coat the residues, thus limiting their migration within the cavity 116.

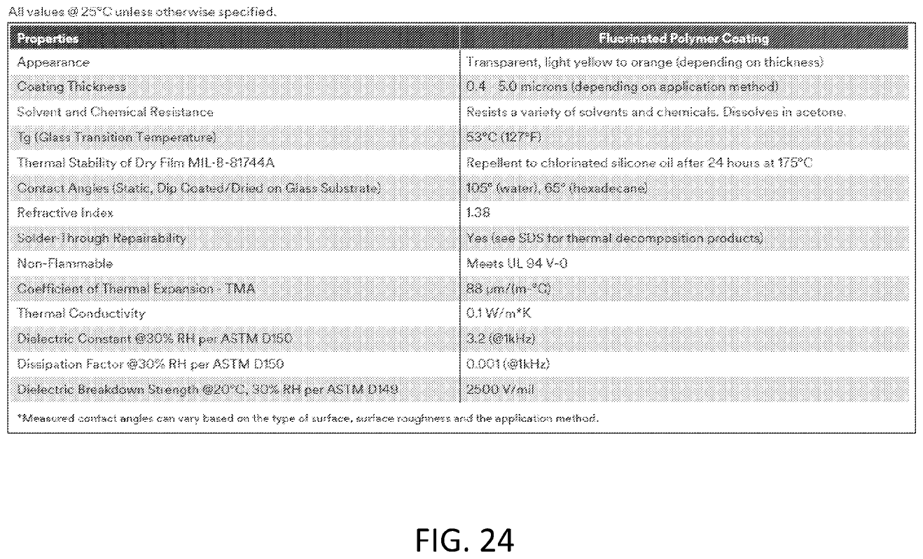

The oleophobic coating 140 may be formed of a fluoropolymer. For example, the oleophobic coating 140 may be formed of a highly cross-linked fluoropolymer with a low surface energy, such as 3M™ EGC-2788. More generally, the oleophobic coating 140 may be formed from a fluoropolymer (e.g., cross-linked fluoropolymers, or non-cross-linked fluoropolymers) including, but not limited to, 3M™ Novec™ 2708 and 3M™ EGC-2788. FIG. 24 further provides material properties of 3M™ Novec™ 2708. The oleophobic coating 140 may not include silicone, acrylic, and/or other hydrocarbons that are oleophilic.

The oleophobic coating 140 may be applied after the sealant 130 is applied to the device 110 and the substrate 120. In one example, the computing system 100c may be dip coated by dipping the computing system 100c in a bath of an oleophobic solution (e.g., a fluoropolymer solution), which includes an oleophobic material and a solvent. In some implementations, the oleophobic solution includes less than or equal to about 10 wt % oleophobic material and/or greater than or equal to about 90 wt % solvent. In some implementations, the oleophobic solution includes less than or equal to about 5 wt % oleophobic material and/or greater than or equal to about 95 w % solvent. The oleophobic solution may readily infiltrate the cavity 116 through the opening 114. After removing the computing system 100c from the bath, the oleophobic coating may be cured. The curing process may be facilitated, in part, by heating the computing system 100c to an elevated temperature to vaporize the solvent (e.g., a temperature of about 120° C.).

It should be appreciated that, in some implementations, the oleophobic coating 140 may be applied before the sealant 130 is applied to the device 110 and the substrate 120. For example, the computing system 100c may be dip coated in an oleophobic solution and the sealant 130 may be applied thereafter. Although the surfaces of the sealant 130 are uncoated with the oleophobic coating 140 in this approach, the oleophobic coating 140 present on the other surfaces of the cavity 116 may still be sufficient to appreciably repel coolant liquid from infiltrating the cavity 116.

In another example, a syringe containing an oleophobic solution may be injected into the cavity 116 through the opening 114. The oleophobic coating formed within the cavity 116 may be cured in the same manner described above. In this example, the oleophobic coating may only be applied to the surfaces within the cavity 116 unlike the dip coating process described above, which also coats the exterior surfaces of the computing system 100c.

It should also be appreciated that, in some implementations, the computing systems disclosed herein may include an oleophobic coating 140 applied to the device 110 and the substrate 120 without any sealant 130, underfill 134, or protective coating 180. Said another way, the computing system may only include the oleophobic coating 140 to protect the electrical interconnects between the device 110 and the substrate 120 from exposure to the coolant liquid 220. The oleophobic coating 140 may be applied in the same manner as described above, e.g., by dip coating or via syringe, without the application of the sealant 130. In some implementations, the oleophobic coating 140 may have the same properties and/or perform the same function as the protective coatings discussed in Section 3.

### 1.4 An Example Edge Sealed Electronic Device With an Extension Plate

As described in Section 1.3, the coolant liquids typically used in two-phase immersion cooling systems readily wet the surfaces of the computing systems disclosed herein. In particular, the coolant liquid may readily wet the sealant, which in the computing systems 100b and 100c described above, are located near the outermost electrical interconnects (e.g., the BGA 112) of the device 110. As the coolant liquid wets the sealant, undesirable contaminants may be deposited onto the sealant. Over time, these contaminants may accumulate on the sealant and extend closer towards the outermost electrical interconnects. Once these contaminants physically contact the outermost electrical interconnects, an electrical short may occur causing the computing system to fail. The time period for this failure mechanism to occur depends on the distance separating the sealant 130 and the outermost electrical interconnects.

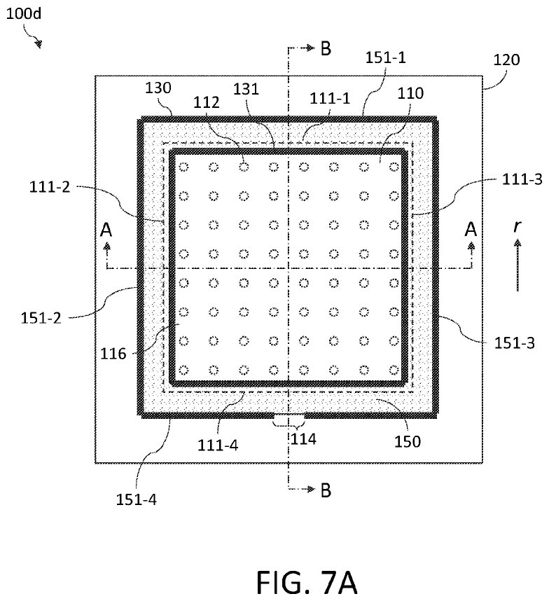

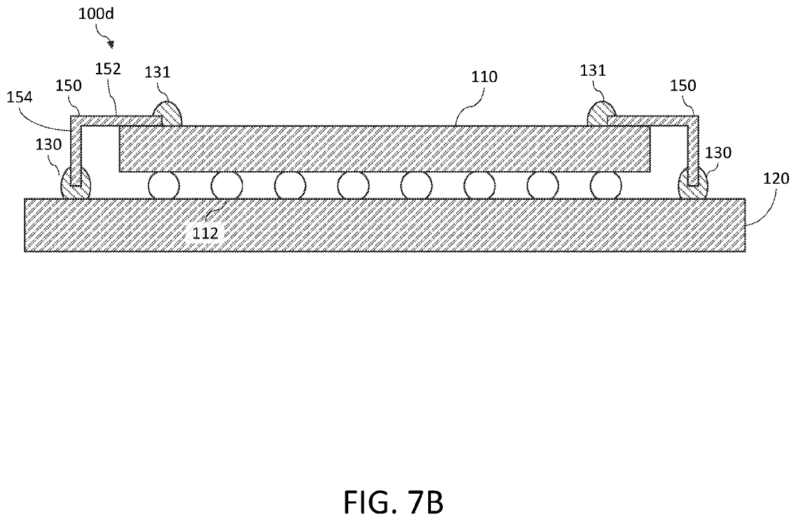

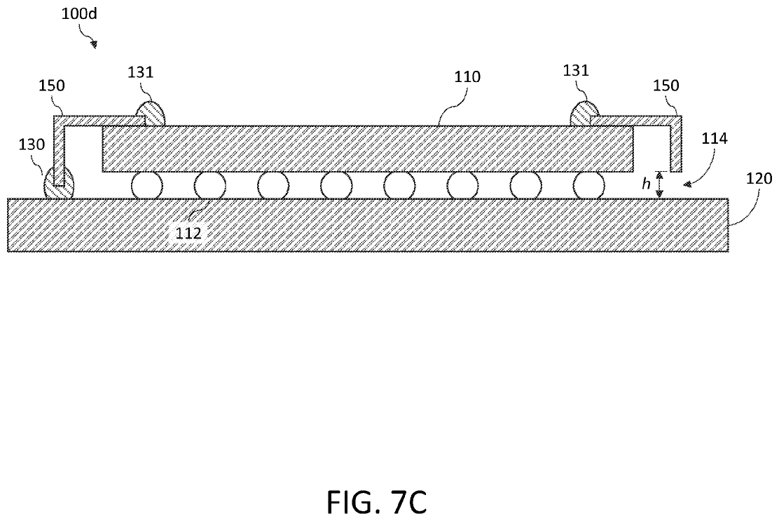

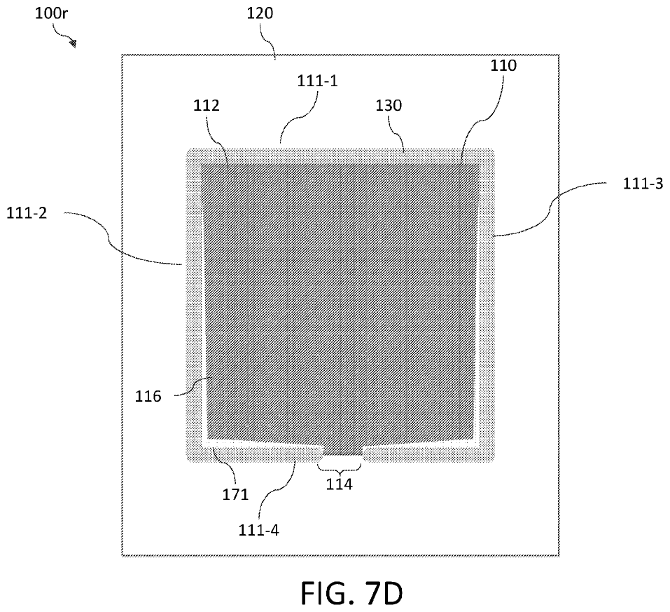

In some implementations, this distance may be increased by separating the sealant from the outermost electrical interconnects. This may be accomplished, for example, by incorporating an extension plate to change the location of the sealant with respect to the electrical interconnects. In one example, FIGS. 7A-7C show a computing system 100d that includes an extension plate 150. The computing system 100d may include several of the same components and/or features as the computing systems 100b and 100c. The computing system 100d may further operate in a similar manner to the computing systems 100b and 100c, unless indicated otherwise. For brevity, repeated discussions of these features may not be provided below.

As shown, the computing system 100d may once again include a device 110 mounted to a substrate 120 via a ball grid array 112. The extension plate 150 may be mounted to the device 110 and extend from the edges 111-1, 111-2, 111-3 and 111-4 of the device 110 over the substrate 120, thus covering a larger area of the substrate 120 compared to the device 110. The sealant 130, in turn, may be applied to the edges 151-1, 151-2, 151-3, and 151-4 of the extension plate 150 and the substrate 120 to form an edge bond that seals the gaps formed between the extension plate 150 and the substrate 120. In this manner the device 110, the substrate 120, the extension plate 150, and the sealant 130 together form a cavity 116 to trap one or bubbles of gas. In some implementations, the cavity 116 of the computing system 100d may be larger than the cavities 116 of the computing systems 100b or 100c if the devices 110 are the same size.

As shown in FIG. 7B, the extension plate 150 may include a horizontal portion 152 that mounts onto the device 110 and a vertical portion 154 that extends downwards from the horizontal portion 152 towards the substrate 120. In some implementations, the extension plate 150 may be mounted to various components of the device 110 including, but not limited to, a lid and a PCB of the device 110. This may be accomplished, for example, by applying a sealant 131 to the inner edges of the extension plate 150 and the device 110, as shown in FIG. 7A, to form another edge bond. The sealant 131 may be formed from the same material as the sealant 130 (i.e., the sealants 130 and 131 have identical material compositions). It should be appreciated, however, that the extension plate 150 may be attached to the device 110 in other ways. For example, the extension plate 150 may be attached via soldering, welding, and/or the like.

In some implementations, the vertical portion 154 of the extension plate 150 may be dimensioned such that it does not physically contact the substrate 120. Said another way, the extension plate 150 may be deliberately dimensioned to form a gap with the substrate 120. This may allow the extension plate 150 to sit flush onto the device 110 and/or reduce the likelihood of the extension plate 150 contacting another electrical component on the substrate 120 (e.g., a wire trace). The sealant 130 may accordingly fill the gap formed between the vertical portion 154 and the substrate 120.

The sealant 130 may be applied to the edges 151-1, 151-2, 151-3, and 151-4 in a similar manner as the sealant 130 in the computing systems 100b and 100c. For example, FIG. 7A shows the sealant 130 may cover all of the edges 151-1, 151-2, and 151-3 and a portion of the edge 151-4 such that an opening 114 is formed along the edge bond. In some implementations, the opening 114 may be formed by not applying sealant 130 along a portion of the edge 151-4. In some implementations, the dimensions of the opening 114 may be altered, for example, by adjusting the dimensions of the vertical portion 154 at the opening 114. For example, FIG. 7C shows the vertical portion 154 near the opening 114 may be dimensioned to form a gap with a height, h, with the substrate 120. This gap may be larger (or smaller) than other sections of the extension plate 150.

The extension plate 150 may be formed of various materials including, but not limited to, copper, nickel-plated copper, and aluminum.

It should be appreciated that the extension plate 150 in the computing system 100d is a non-limiting example. More generally, the extension plate 150 may extend from one or more of the edges of the device (e.g., the edges 111-1, 111-2, 111-3, and/or 111-4). For example, the extension plate 150 may only extend from the bottom edge(s) of the device 110 and/or edges with openings 114, which are more susceptible to the infiltration of coolant liquid. In another example, the extension plate 150 may be shaped such that the gap is relatively large near the opening 114 and decreases in size as the distance from the opening 114 increases. In yet another example, the extension plate 150 may be shaped such that the gap corresponds to the volume of coolant liquid that infiltrates the cavity via wicking along the sealant 130, which typically varies as a function of position along the sealant 130. For instance, the gap may be relatively larger at positions where the volume of coolant liquid is relatively larger and relatively smaller at positions where the volume of coolant liquid is relatively smaller.

It should also be appreciated that, in some implementations, a gap may be formed without an extension plate. For example, the device 110 (e.g., the interposer) and/or the electrical interconnects 112 may be shaped and/or arranged such that a larger gap forms when a sealant 130 is applied along the edges of the device 110. For example, FIG. 7D shows a computing system 100r where a variable sized gap 171 is formed along the edges 111-2, 111-3, and 111-4 of the device 110 between the sealant 130 and the outermost electrical interconnects 112.

It should also be appreciated that the oleophobic coating described in Section 1.3 with respect to the computing system 100c may also be applied to the computing system 100d. For example, an oleophobic coating may be applied (e.g., via dip coating or syringe) such that at least the interior surfaces of the device 110, the substrate 120, the sealant 130, and the extension plate 150 are coated with the oleophobic coating.

### 1.5 An Example Edge Sealed Electronic Device With All Edges Sealed

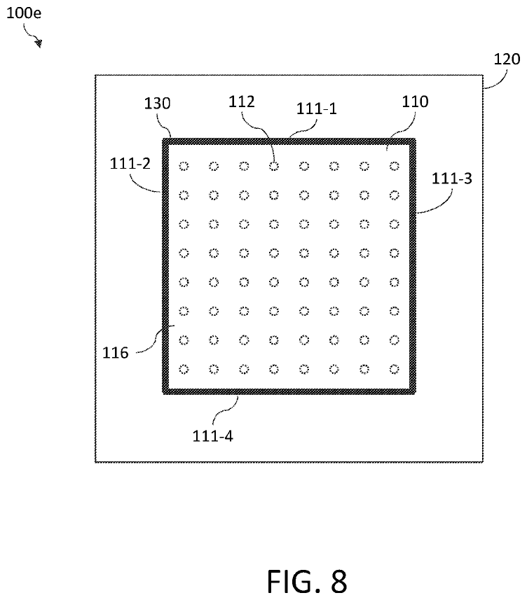

It should be appreciated that the foregoing examples of computing systems 100 with edge sealed devices (e.g., the computing systems 100a, 100b, 100c, and 100d) are non-limiting examples. In some implementations, a computing system may include a device with a sealant applied to all its edges. In other words, the edge bond provides no opening to allow a fluid to pass into and/or out of the cavity formed by the device, the substrate, and the sealant. This, in turn, provides more flexibility to install the device in different orientations within an immersion cooling system. For example, FIG. 8 shows an example computing system 100e where the edges 111-1, 111-2, 111-3, and 111-4 are fully covered by the sealant 130. The computing system 100e may be suitable when, during operation, the gas within the cavity 116 is not appreciably heated (e.g., by the electrical connects between the device 110 and the substrate 120) and/or the pressure within the cavity does not appreciably increase.

As described above, the sealant 130 may be cured at an elevated temperature. In some implementations, the curing temperature may range from about 23° C. to about 150° C., including all values and sub-ranges in between. FIG. 16C shows another example computing system 1001 where a sealant 130 (e.g., Zymet UA-2605-B) is applied in one pass around all edges of the device 110. Thereafter, the sealant 130 is cured at a temperature of 130° C. for 10 minutes.

In some instances, the curing temperature may be sufficiently high such that the corresponding increase in the gas pressure within the cavity 116 causes the sealant 130 to fail when the cavity 116 is fully sealed, such as in the computing system 100e. For example, the sealant 130 may rupture and/or delaminate. To appreciably reduce or, in some instances, mitigate the occurrence of failures when curing the sealant 130, the sealant 130 may be applied such that an opening is formed, such as the opening 114 in the computing system 100b. The opening may thus provide a way to relieve any pressure buildup within the cavity 116 when the sealant 130 is cured. Unlike the opening 114 of the computing system 100b, the opening formed in this example may be formed on any edge of the device 110.

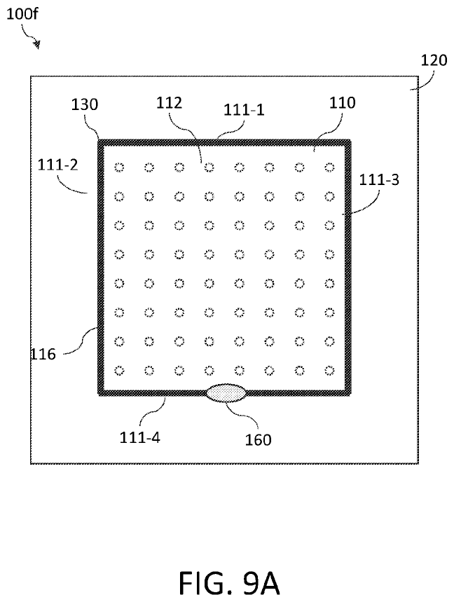

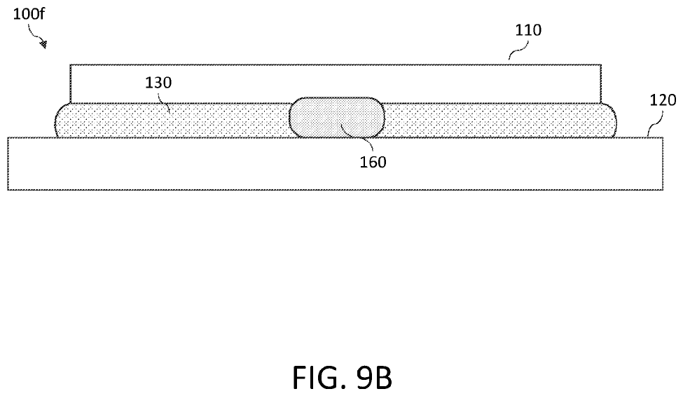

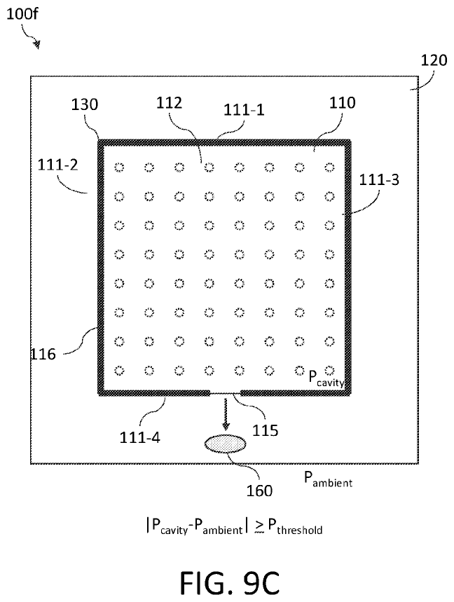

Once the sealant 130 is cured, the opening 115 may be sealed with a plug. For example, FIGS. 9A and 9B show an example computing system 100f with a plug 160 inserted into the opening 115 (hidden by the plug 160). The plug 160 may be an epoxy or an adhesive. For example, the plug 160 may be formed by applying an ultraviolet (UV) curable adhesive (e.g., Zymet UA-2701) to fill the opening 115 and thereafter exposing the adhesive to UV radiation to cure the adhesive. In this manner, all the sides of the device 110 in the computing system 100f may be sealed similar to the device 110 in the computing system 100e. FIG. 16D shows another example computing system 100m where two sealants are applied to cover the edges of the device 110 in a two-pass process. The first sealant 130 (e.g., Zymet UA-2605-B) is applied during a first pass such that an opening (e.g. an opening 114) is formed. Thereafter, the sealant 130 is cured at a temperature of 130° C. for 10 minutes. The opening formed by the sealant 130 provides ventilation for air trapped in the cavity formed by the device 110, the sealant 130, and the underlying substrate. Once the sealant 130 is cured, a second sealant may be applied to form a plug 160 (e.g., Zymet UA-2701) during a second pass to cover the opening formed by the sealant 130. Once the second sealant is applied, it is cured using ultraviolet (UV) radiation using, for example, a UV wand.

It should be appreciated that the pressure within the cavity 116 may increase during operation due, for example, to heat generated at the BGA 112. In some instances, this increase in pressure may also be sufficient to cause the sealant 130 to fail when the cavity 116 is fully sealed, such as in the computing system 100e or 100f.

For the computing system 100f, failures during operation due to increases in pressure within the cavity 116 may be appreciably reduced or, in some instances, prevented by the plug 160 being removable. For example, the plug 160 may be configured to separate from the sealant 130, the device 110, and/or the substrate 120, thus exposing the opening 115 and relieving any pressure buildup within the cavity 116, as shown in FIG. 9C. In this manner, the plug 160 may function as a one-time venting valve to prevent sudden failure of the computing system due to excessive pressure buildup within the cavity 116. In some implementations, plug 160 may be separated when the pressure difference between the cavity (P_{cavity}) and the ambient environment (P_{ambient}) is greater than or equal to a threshold pressure (P_{threshold}). The threshold pressure may be, for example, less than or equal to about 1 pound per square inch (psi), including all values and sub-ranges in between.

Although the opening 115 may allow coolant liquid to thereafter enter the cavity 116 and, hence, potentially deposit contaminants onto sensitive components (e.g., the BGA 112), this outcome may be a preferable over a sudden failure of the system. For example, if the opening 115 is located on the bottom edge of the device 110, any coolant liquid that enters the cavity 116 and boils may generate coolant vapor that is then trapped within the cavity 116 as in the computing system 100b. Even if the opening 115 is located on the left edge, the right edge, or the top edge of the device 110, the relatively small dimensions of the opening 115 may reduce the rate at which contaminants accumulate within the cavity 116 and, in particular, on the BGA 112.

Once the plug 160 is removed, it may be preferable for the plug 160 to float to the top of the coolant liquid bath so that it can be removed manually or by a filtration system. This may be facilitated, in part, by the plug 160 being formed of a material with a lower density than the coolant liquid. For example, the density of the plug 160 may be less than about 1600 kg/m³, including all values and sub-ranges in between. Additionally, the plug 160 may be sufficiently soft and, in some instances, malleable to facilitate application during assembly and/or removal from the system 100f as described above.

In some implementations, increases in pressure within the cavity 116 during operation may be compensated, in part, by sealing the device 110 such that the cavity 116 is at a lower initial pressure before operation. For example, the sealant 130 may be applied to the edges of the device 110 in a low vacuum environment. In some implementations, the low vacuum environment may be at a pressure less than or equal to about 0.9 atm. In some implementations, the low vacuum environment may be at a pressure less than or equal to about 0.8 atm.

### 1.6. An Example Edge Sealed Electronic Device With a Boiler Plate

The electronic devices disclosed herein may include a boiler plate to facilitate cooling in an immersion cooling system. For example, the device may be coupled to a boiler plate via a thermal interface material. The boiler plate may further include a boiling enhancement coating to promote boiling of the coolant liquid. Further, the boiler plate and the device may be securely coupled to the substrate by a retention plate. In some implementations, an edge bond may be formed along the edges of the boiler plate and/or the retention plate instead of the device itself.

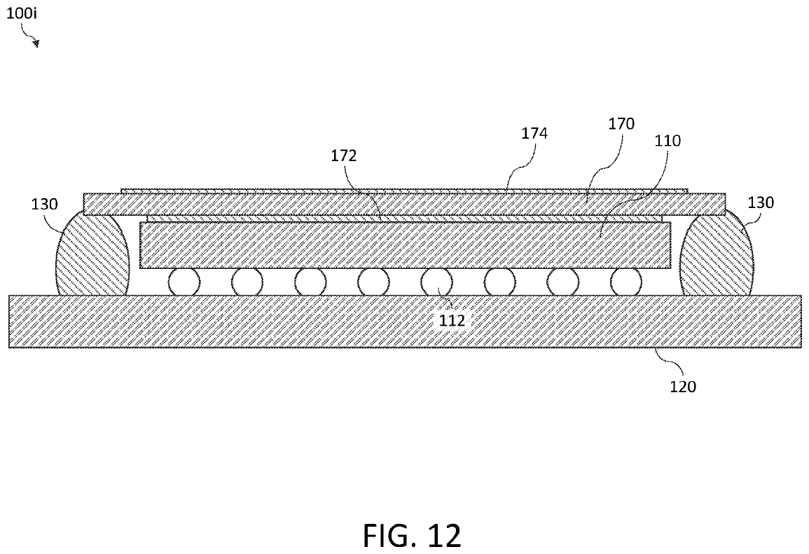

For example, FIG. 12 shows a computing system 100i with a device 110 and a boiler plate 170 coupled to the device 110 via a layer of thermal interface material 172. The boiler plate 170 may further include a boiling enhancement coating 174. Typically, the boiler plate 170 is larger in size than the device 110 and thus extends beyond the edges of the device 110 as shown in FIG. 12. Accordingly, sealant 130 may be applied along the edges of the boiler plate 170 to form at least a partially enclosed cavity containing the device 110, the thermal interface material 172, and the BGA 112.

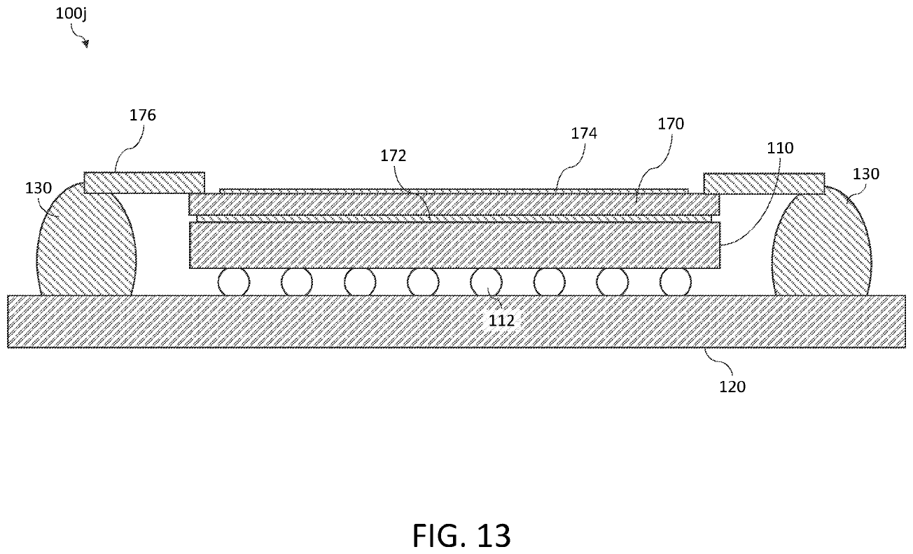

In another example, FIG. 13 shows a computing system 100j with a device 110, a boiler plate 170, and a retention plate 176 to securely couple the device 110 and the boiler plate 170 to the substrate 120, e.g., via fasteners (not shown). In some instances, the boiler plate 170 may be the same size as the device 110, thus it may be preferable to apply sealant 130 to the edges of the retention plate 176, which extend beyond the edges of the boiler plate 170 and/or the device 110.

### 1.7 An Example Method of Assembling a Computing System With an Edge Sealed Electronic Device

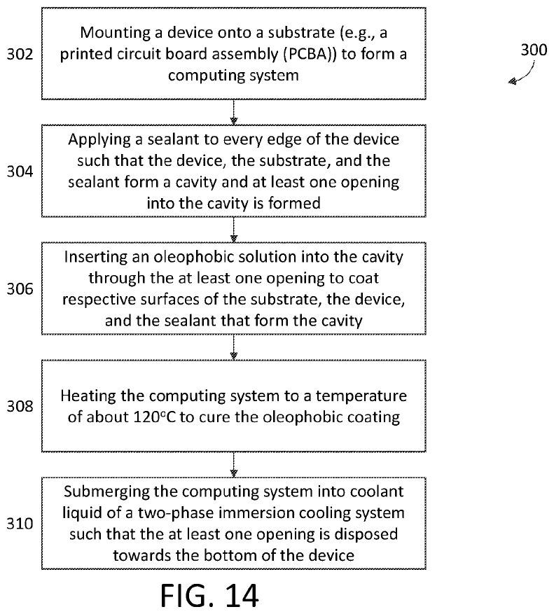

FIG. 14 shows an example method 300 for assembling a computing system according to the inventive concepts disclosed herein. The method 300 begins at step 302 by mounting a device to a substrate to form a computing system. In some implementations, the computing system may include multiple surface-mounted devices. Accordingly, each of these devices may be mounted at step 302. Thereafter, at step 304, the sealant may be applied to the edges of each of the devices and the substrate. Accordingly, the device, the substrate, the extension plate (if present), and the sealant may form a cavity (e.g., the cavity 116) to trap one or more bubbles of gas when the computing system is submerged in coolant liquid.

The sealant may be applied in the manner described above, with the sealant substantially covering the edges of the device (or, alternatively, the extension plate if present) except for portions where an opening is deliberately formed (e.g., the opening 114). For example, an opening may be formed by applying the sealant onto a portion of the edges of a device so that the remaining portion of the edges that are left exposed provide the opening. In another example, an opening may be formed by applying the sealant along all the edges of the device and thereafter removing a portion of the sealant to form the opening. Portions of the sealant may be removed in various ways including, but not limited to, drilling, piercing, cutting, etching, and/or the like. It should be appreciated that, in some implementations, the sealant may be applied to cover all edges of the device without any opening.

If an opening is formed in the sealant, an oleophobic coating may be applied to coat the surfaces of the device, the substrate, the extension plate (if present), and the sealant that forms a cavity at step 306 once the sealant is cured and/or hardened. This may be accomplished, for example, by dip coating the computing system in a bath of oleophobic solution, or injecting the oleophobic solution into the cavity using a syringe. The oleophobic solution may contain, for example, a fluoropolymer as described in Section 1.3. Once the oleophobic solution is applied and an oleophobic coating is formed, the oleophobic coating may thereafter be cured at step 308. This may be accomplished by heating the computing system to an elevated temperature (e.g., a temperature of about 120° C.) to vaporize the solvent in the oleophobic coating

Once the oleophobic coating is formed, the computing system is ready for installation in the two-phase immersion cooling system. Thus, at step 310, the computing system may be installed, in part, by submerging the computing system into coolant liquid stored in a tank in a two-phase immersion cooling system. The computing system may be oriented such that the at least one opening is disposed towards the bottom of the device.

### 2. An Example Electronic Device With Underfill

Another example approach to protect electronic devices from exposure to a coolant liquid in an immersion cooling system (e.g., a two-phase immersion cooling system) is to apply an underfill to surround the electrical interconnects between a device and a substrate (e.g., a PCB) supporting the device. Compared to the sealants for edge bonding described above, an underfill may be applied with less precision provided the underfill is able to infiltrate and fill the space between the device and the substrate. The underfill may thus provide a barrier that prevents coolant liquid from physically contacting the electrical interconnects. In this manner, the underfill may protect the electrical interconnects (e.g., the BGA) from various failure modes described above.

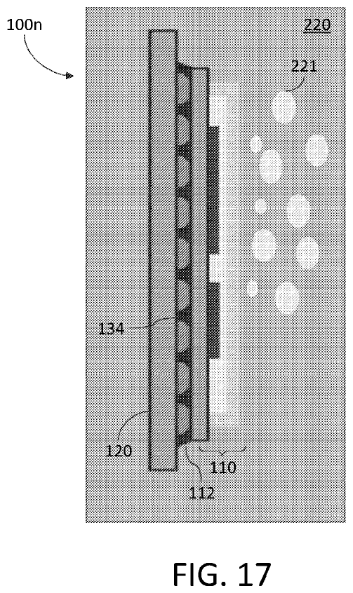

FIG. 17 shows an example computing system 100n with a device 110 mounted to a substrate 120 (e.g., a PCB) via a BGA 112. As shown, an underfill 134 may be disposed between the device 110 and the substrate 120. The underfill 134 may fill the interstitial space in and around the electrical interconnects (e.g., solder balls 112). In some implementations, each solder ball 112 may be surrounded by the underfill 134 such that no portion of the solder ball 112 physically contacts the coolant liquid 220 when the system 100n is installed into an immersion cooling system. In some implementations, the underfill 134 may fill the entirety of the space between the device 110 and the substrate 120. Said another way, there may be little to no air trapped between the device 110 and the substrate 120 when the underfill 134 is applied.

For example, the underfill 134 prevents signal degradation by displacing immersion coolant liquid 220 from the region (e.g., the BGA region) between the device 110 and the substrate 120, thus reducing the effective area of the electrical traces (e.g., the solder balls 112) exposed to the coolant liquid 220. Generally, signal loss caused by the presence of coolant liquid 220 is proportional to both the proximity and contact area of the electrical traces with the coolant liquid 220. Thus, the underfill 134 may reduce cumulative signal loss caused by exposure to the coolant liquid 220. Moreover, the underfill 134 may be formed from a material having a dielectric constant closer to air (i.e., less than the coolant liquid 220), which may further reduce signal degradation.

In another example, the underfill 134 may mitigate failures caused by the accumulation of contaminants near or on the BGA 112. As described above, the underfill 134 displaces the coolant liquid 220 near the BGA 112, which prevents the coolant liquid 220 from boiling at or near the BGA 112. This, in turn, prevents the distillation of contaminants on or near the BGA 112. Instead, the coolant liquid 220 may only boil at desired portions of the device 110 (e.g., the lid 118).

In yet another example, the underfill 134 may mitigate electrochemical migration by preventing the deposition of hydrocarbons (e.g., oils) dissolved within the coolant liquid 220 near or on the BGA 112. Electrochemical migration requires the deposition of an oil that connects two or more solder balls 112 together. Thus, by eliminating the deposition of oil, this failure mode is also eliminated.

The underfill 134 may preferably be chemically compatible with the coolant liquid 220. For example, the underfill 134 may be formed from a material that is chemically inert with the coolant liquid 220 and/or does not degrade when exposed to the coolant liquid 220. In another example, the underfill 134 may be applied without destroying the device 110 (i.e., its application is non-destructive). In yet another example, the underfill 134 may not provide structural support to the device 110 (i.e., the device 110 is mechanically supported by the BGA 112 and the substrate 120). In yet another example, the underfill 134 may be formed from a material having low dielectric loss (e.g., a low extinction coefficient).

The underfill 134 may be formed from various materials including, but not limited to, 3M Scotch-Weld DP420, Zymet UA-2605-B, and Zymet X2821. Preferably, the underfill 134 has a resistivity, dielectric constant, dielectric strength, and coefficient of thermal expansion within 25%, preferably within 5% to 10%, of one or both of 3M Scotch-Weld DP420, Zymet UA-2605-B, and/or Zymet X2821. FIG. 15 further provides material properties for some of the foregoing materials. Preferably, the dielectric constant of the underfill 134 is less than the dielectric constant of the coolant liquid 220. Preferably, the dielectric constant of the underfill 134 is less than 1.8, such as 1.7, or 1.6, or 1.5, or 1.4, or 1.3 or less.

The underfill 134 may be injected into the cavity between the device 110 and the substrate 120. In some implementations, the underfill 134 may be formed from a material that readily wets the surfaces of the device 110, the substrate 120, and/or the BGA 112. Once the underfill 134 is applied, it may then be cured. The curing process may be facilitated, in part, by heating the underfill 134 to an elevated temperature for a predetermined period of time.

### 3. Examples of Electronic Devices With Protective Coatings

Yet another approach to protect electronic devices from exposure to a coolant liquid in an immersion cooling system (e.g., a two-phase immersion cooling system) is to apply a protective coating onto sensitive electronic components of the device to reduce the likelihood of or, in some instances, prevent various failure mechanisms related to the exposure of the electronic device to a coolant liquid of a two-phase immersion cooling system. The coating may be specifically configured to suppress the boiling of coolant liquid on or near electrical components of the device. Accordingly, the coating may exhibit several properties to facilitate the suppression of boiling. It should be appreciated that, in some implementations, the coatings disclosed herein may be formed from the same or similar materials described above.

For example, the coating may form a smooth surface to reduce or, in some instances, prevent boiling of coolant liquid that physically contacts the surface of the coating, e.g., by reducing the number of nucleation sites on the surface that can form a bubble of coolant vapor. By suppressing boiling at or near the portion of the electronic device with the coating, the deposition and accumulation of contaminants (e.g., hydrocarbon contaminants) can be appreciably reduced.

The smoothness of the coating may be evaluated quantitatively using various surface roughness metrics. For example, a peak surface roughness can be used, which is defined as the depth between the highest peak and the lowest valley across a measured surface. In some implementations, the peak surface roughness is less than or equal to about 10 μm. More preferably, the peak surface roughness is less than or equal to about 5 μm. Even more preferably, the peak surface roughness is less than or equal to about 1 μm. In another example, a root mean square (RMS) surface roughness can be used, which is defined as the RMS of the surface variations across a measured surface. In some implementations, the RMS surface roughness is less than or equal to about 10 μm. More preferably, the RMS surface roughness is less than or equal to about 5 μm. Even more preferably, the RMS surface roughness is less than or equal to about 1 μm. The term “about,” when used to describe the surface roughness of the coating, is intended to cover variations that may arise due to application of the coating. For example, “about 10 μm” may correspond to the following dimensional ranges: 9.9 μm to 10.1 μm (+/−1% variation), 9.8 μm to 10.2 μm (+/−2% variation), 9.7 μm to 10.3 μm (+/−3% variation), 9.6 μm to 10.4 μm (+/−4% variation), 9.5 μm to 10.5 μm (+/−5% variation), including all values and sub-ranges in between.

In another example, the coating may have a low thermal conductivity to reduce heat transfer from the portion of the electronic device covered by the coating to the coolant liquid, which also suppresses or, in some instances, prevents boiling of the coolant liquid. In some implementations, the thermal conductivity of the coating may be less than or equal to about 0.3 W/m-K, less than or equal to about 0.2 W/m-K, or less than or equal to about 0.1 W/m-K. The term “about,” when used to describe the thermal conductivity of the coating, is intended to cover variations that may arise due to material composition and/or morphology. For example, “about 0.1 W/m-K” may correspond to the following ranges: 0.099 W/m-K to 0.101 W/m-K (+/−1% variation), 0.098 W/m-K to 0.102 W/m-K (+/−2% variation), 0.097 W/m-K to 0.103 W/m-K (+/−3% variation), 0.096 W/m-K to 0.104 W/m-K (+/−4% variation), 0.095 W/m-K to 0.105 W/m-K (+/−5% variation), including all values and sub-ranges in between.

In another example, the coating may be hydrophobic and/or oleophobic to repel water/aqueous solutions and oils, respectively, away from the portion of the electronic device covered by the coating. A hydrophobic coating may appreciably reduce or, in some instances, prevent corrosion from acids in the coolant liquid. An oleophobic coating may appreciably reduce or, in some instances, prevent the deposition of hydrocarbon contaminants. In some implementations, a hydrophobic and/or oleophobic coating may prevent coolant liquid from penetrating through, for example, a through-hole of a PCB. The coating may also repel contaminants in the coolant liquid, such as particulates, dissolved water, high molecular weight oils and/or other non-volatile residues.

The hydrophobicity and/or the oleophobicity of the coating may be evaluated based on a contact angle between a droplet of water or oil, respectively, placed on a surface of the coating. In some implementations, contact angle with water and/or oil is greater than or equal to 90 degrees, greater than or equal to about 100 degrees, greater than or equal to about 110 degrees, greater than or equal to about 120 degrees, greater than or equal to about 130 degrees, greater than or equal to about 140 degrees, or greater than or equal to about 150 degrees. The term “about,” when used to describe the contact angle, is intended to cover measurement error. For example, “about 100 degrees” may correspond to the following ranges: 99 degrees to 101 degrees (+/−1% variation), 98 degrees to 102 degrees (+/−2% variation), 97 degrees to 103 degrees (+/−3% variation), 96 degrees to 104 degrees (+/−4% variation), 95 degrees to 105 degrees (+/−5% variation), including all values and sub-ranges in between.

The coating is preferably formed from an inorganic material to reduce or, in some instances, prevent additional contamination of the coolant liquid with organic materials. For example, the coating may be formed from a highly cross-linked fluoropolymer with a low surface energy, such as 3M™ EGC-2788. More generally, the coating may be formed from a a fluoropolymer (e.g., cross-linked fluoropolymers, or non-cross-linked fluoropolymers) including, but not limited to, 3M™ Novec™ 2708 and 3M™ EGC-2788. Preferably, the fluoropolymer has a solvent and chemical resistance, glass transition temperature, thermal stability, coefficient of thermal expansion, thermal conductivity, dielectric constant, dissipation constant, and dissipation factor within 25%, preferably within 5% to 10%, of one or both of 3M™ Novec™ 2708 and 3M™ EGC-2788.

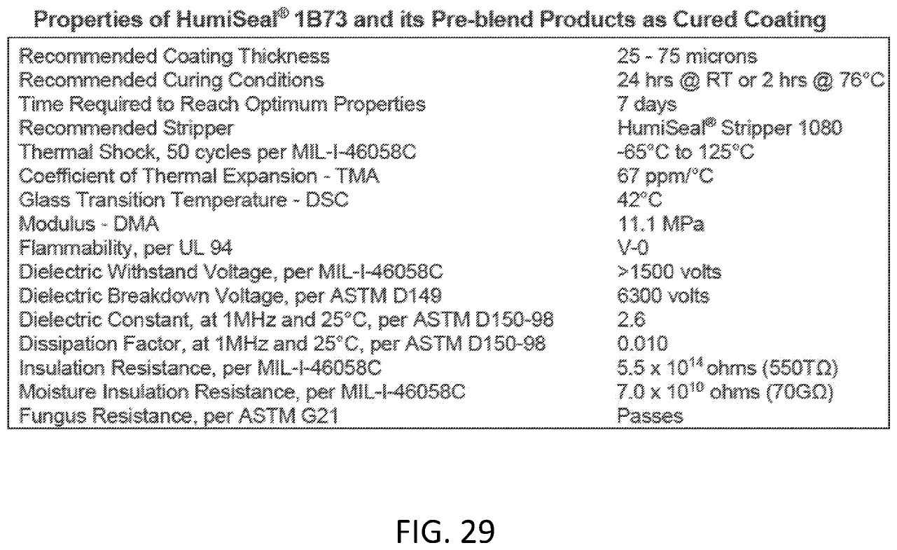

It should be appreciated, however, that some organic materials may be used to form the coating so long as contamination of the coolant liquid with organic compounds is low. For example, the coating may be an acrylic-based conformal coating, which typically forms a smooth surface to suppress boiling of coolant liquid. Example acrylic materials include, but are not limited to, HumiSeal® 1B73. FIG. 29 further provides material properties of HumiSeal® 1B73. Preferably, the acrylic material has a coefficient of thermal expansion, glass transition temperature, modulus-DMA, dielectric withstand voltage, dielectric breakdown voltage, dielectric constant, insulation resistance, and moisture insulation resistance within 25%, preferably within 5% to 10%, of HumiSeal® 1B73. In some implementations, a double layer may be formed by first applying the fluoropolymer, on top of which the acrylic-based conformal coating is applied; or alternatively, first applying the acrylic-based conformal coating and then applying the fluoropolymer.

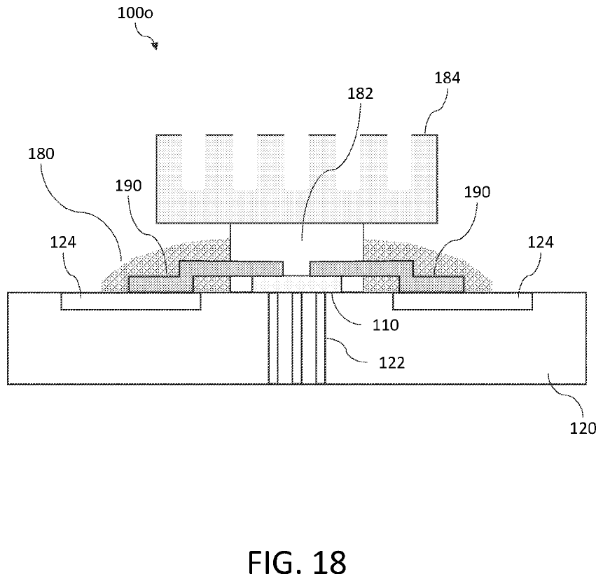

In some implementations, the coating may be selectively applied to certain electronic devices and/or certain portions of electronic devices. For example, FIG. 18 shows a computing system 1000 with a surface mounted field effect transistor (FET). As shown, the system 1000 includes a device 110 (e.g., a transistor) electrically coupled to a substrate 120 (e.g., a PCB) via multiple electrical vias 122. The device 110 may also be electrically coupled to one or more contact pads 124 on the substrate 120 via corresponding electrical leads 190. The device 110 and the leads 190 may be surrounded by an encapsulant 182. A heat sink 184 may be mounted onto the encapsulant to dissipate heat generated by the device 110. The leads 190 are typically exposed to the ambient environment in conventional systems. In the system 1000, a coating 180 is applied to cover and encapsulate the solder leads 190, thus forming a protective barrier between the leads 190 and the ambient environment (e.g., coolant liquid).

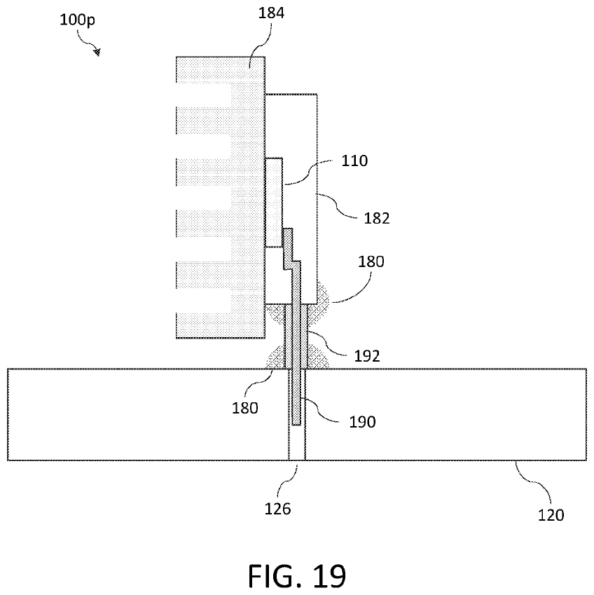

In another example, FIG. 19 shows a computing system 100p with a through-hole mounted FET. As shown, the system 100p includes a device 110 (e.g., a transistor) electrically coupled to a substrate 120 (e.g., a PCB) via a lead 190 inserted into a through hole contact 126 on the substrate 120. The through hole contact 126 may include an opening that extends through the entirety of the substrate 120 and at least a portion or, in some instances, all of the surfaces forming the opening may be formed from an electrically conductive material. The device 110 and the lead 190 may once again be surrounded by an encapsulant 182. Here, the heat sink 184 may be directly coupled to the device 110 and a portion of the encapsulant 182. The heat sink 184 may be oriented such that the fins extend from the encapsulant 182 along an axis parallel to the plane of the substrate 120 (e.g., at a ninety degree angle relative to the heat sink 184 in the system 1000). Accordingly, the device 110 may be disposed above the substrate 120 and supported by the lead 190. A portion of the lead 190 may extend vertically between the device 110 and the substrate 120 to provide sufficient clearance between the heat sink 184 and the substrate 120. The system 100p may further include a sleeve 192 disposed around the portion of the lead 190 located between the device 110 and the substrate 120 to provide a protective cladding. However, gaps may still form between the sleeve 192 and the substrate 120 and/or the encapsulant 182, which, in turn, may allow coolant liquid to directly contact the lead 190. Thus, the system 100p includes a coating 180 applied to portions of the lead 190 and sleeve 192 that are likely to exhibit a gap, e.g., where the sleeve 192 joins the encapsulant 182 and/or where the sleeve 192 joins the substrate 120.

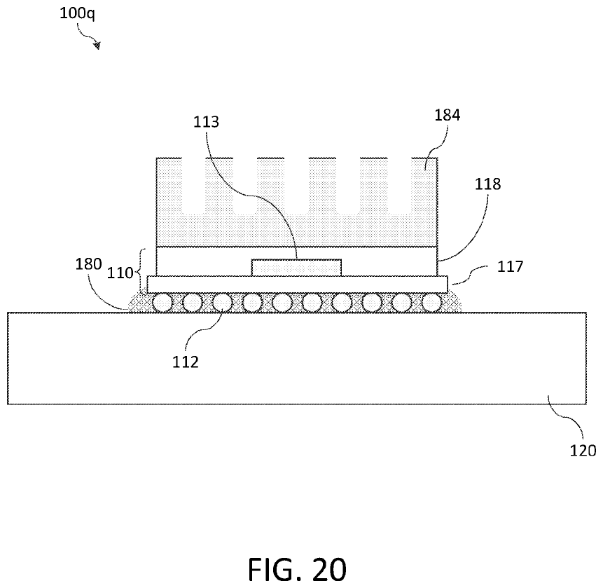

In yet another example, FIG. 20 shows a computing system 100q with a device 110 mounted to a substrate 120 via a BGA 112. As shown, the device 110 includes a chip 113 mounted to a substrate 117 (e.g., an interposer) and a lid 118 to protect the chip 113. A heat sink 184 is mounted directly onto the lid 118. Here, the coating 180 may be applied directly onto the BGA 112 similar to the edge bond or the underfill described in Sections 1 and 2. For example, the protective coating may be applied along the periphery of the device 110 to seal the edges of the device 110 without filling the interstitial space around the BGA 112. In another example, the protecting coating may be applied to fill in the cavity and thus surround and encapsulate the BGA 112.

It should be appreciated that the coatings disclosed herein are not limited to protecting devices of a computing system. More generally, the coatings may be applied to any electrical interconnection in a computing system. For example, FIG. 21 shows a coating 180 may be applied on and around respective through hole contacts 126 of respective PCBs 120a, 120b, and 120c, which are electrically coupled together via respective press-fit pins 194a and 194b. For instance, the coating 180 may be applied to both sides of a given through hole contact 126 to reduce the likelihood of or, in some instances, prevent the infiltration of coolant liquid. In this manner, the signal integrity of any electrical signals transmitted between the pins 194a and 194b the through hole contacts 126 may be preserved.

The coatings disclosed herein may be applied as a liquid solution and thereafter dried before use in two-phase immersion cooling system. The liquid solution may be applied in several ways including, but not limited to, dipping, painting (e.g., with a brush), and spraying (e.g., with a paint spray, paint gun, or paint wand).

In some implementations, the coating may be applied only to a portion of an electronic device, e.g., where electrical contacts are normally exposed. This approach of selectively coating portions of a device may be preferable to reduce material consumption and material costs. However, this approach may be more laborious and/or slower to perform.

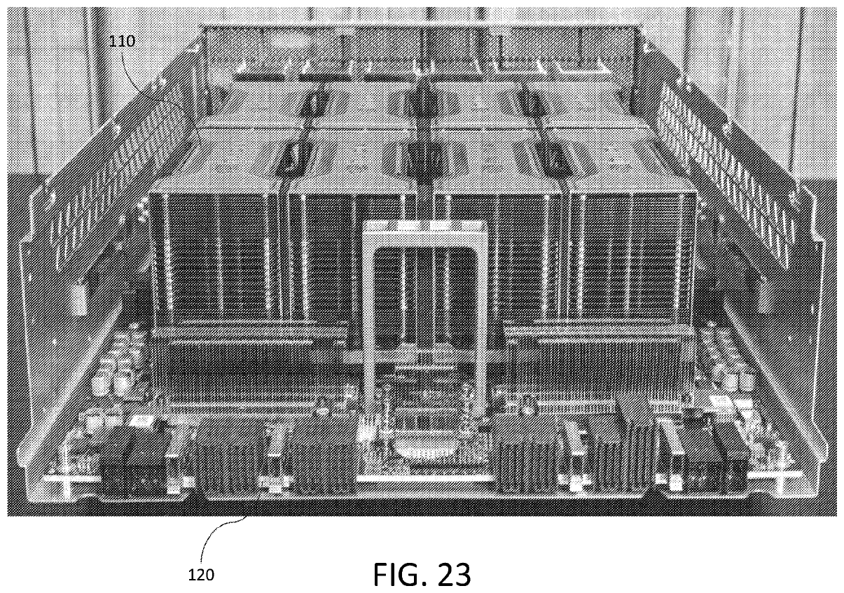

In some implementations, the coating may be applied to cover the entirety of a device, e.g., substantially all surfaces of the device, or the entirety of a computing system (e.g., a PCB with multiple electronic devices mounted thereon) except where boiling of coolant liquid is desired (e.g., along the surface of a lid 118). This may be accomplished, for example, by dipping the device and/or the computing system into a liquid solution, thus substantially coating the surfaces of the device and/or the computing system. The coating may be applied after the computing system is assembled. For example, FIG. 23 shows a GPU server that includes a motherboard 120 with multiple electronic devices 110 (e.g., graphics cards that each have one or more GPUs) mounted thereon. A coating may be applied to the motherboard 120 and some or all of the electronic devices 110 after assembly.

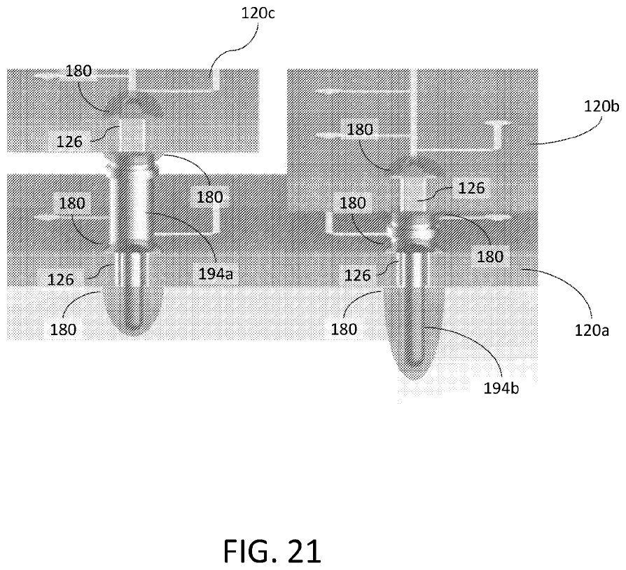

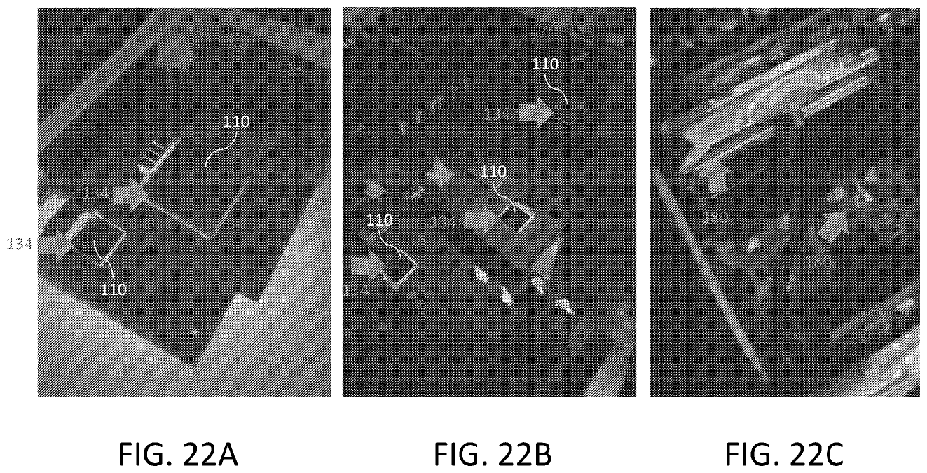

In some implementations, the coatings disclosed herein may be applied in combination with the sealants and/or underfill described in Sections 1 and 2. For example, FIGS. 22A and 22B show electronic devices 110 with underfill 134. The coatings disclosed herein may be applied directly onto the underfill 134. In another example, FIG. 22C shows other types of devices and electrical connections that may be covered by a coating 180. In some implementations, the coatings may have the same properties and/or perform the same function as the oleophobic coatings described in Section 1.3.

### 4. Examples of Electronic Devices With Combinations of Protective Features

In some implementations, a protected electronic device may be assembled using a combination of the sealant described in Section 1, the underfill described in Section 2, and/or the protective coatings described in Section 3. In some implementations, multiple applications of the same sealant and/or coating or different sealants and/or a coatings may be applied to a given device. Combining different protective features and/or adding multiples of a given protective feature may be desirable in some applications, such as increasing the operating lifetime of a device or reducing the risk of manufacturing defects.

In regard to manufacturing defects, the defects may arise during the assembly of an electronic device. When applying a sealant to form an edge bond around a device, the sealant may be applied inconsistently and/or improperly such that some portions of the sealant do not fully cover the gap formed between the device and the substrate. The sealant may also not properly adhere to the device and/or the substrate resulting in delamination of those portions of the sealant. Similar defects may arise when applying a coating to the device. When applying underfill, the underfill may not fully fill the interstitial space between the electrical interconnects (e.g., the solder balls of a BGA). For each of the foregoing defects, the defect may allow coolant liquid to infiltrate the cavity and thus increase the risk of contamination and failure.

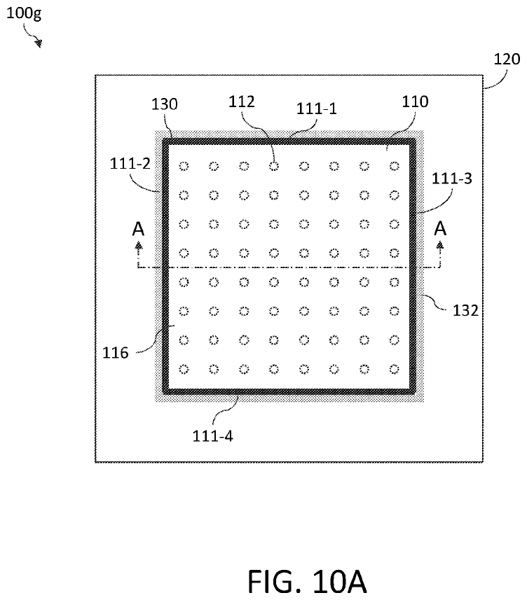

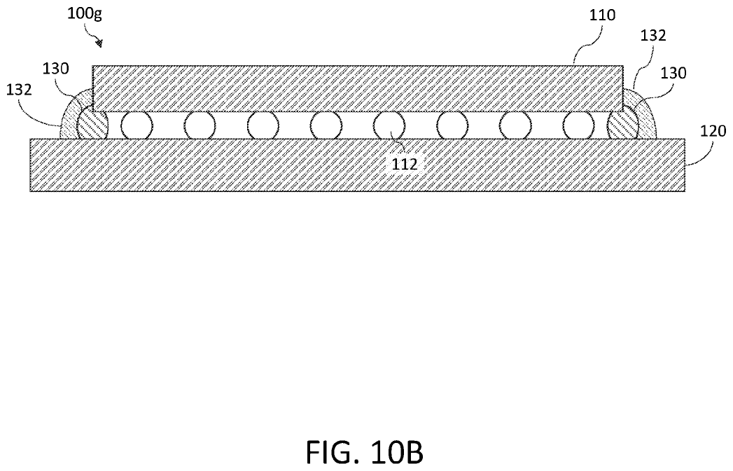

In one example, two layers of sealant may be applied around the edges of a device. FIGS. 10A and 10B show an example computing system 100g with sealants 130 and 132 applied to the edges of the device 110. As shown in FIG. 10B, the sealant 132 may be applied directly onto the sealant 130 such that at least a portion of the sealant 132 physically contacts the device 110 and/or the substrate 120. Thus, the sealants 130 and 132 form two layers. The sealant 132 may be formed from the same material as the sealant 130 or a different material than the sealant 130. Generally, the sealant 132 may be formed from any of the materials listed in Section 1 for the sealant 130. For example, the sealants 130 and 132 may each be formed of Zymet UA-2605-B. In another example, the sealant 130 may be formed of Zymet UA-2605-B and the sealant 132 may be formed of Zymet UA-2701.

The addition of the sealant 132 may appreciably reduce the risk of manufacturing defects. For example, if a manufacturing defect occurs in the sealant 130, the sealant 132 may fix the defect, e.g., by providing additional coverage onto portions of the device 110 where the sealant 130 does not provide sufficient coverage between the device 110 and the substrate 120 and/or is not properly adhered to the device 110 and/or the substrate 120. Although defects may also occur in the sealant 132, the likelihood of defects occurring in both the sealant 130 and the sealant 132 along the same portion of the device 110 in a manner that would cause a device to fail is appreciably small, especially when compared to the risk of device failure when a single layer of sealant is present.

In another example, a protective coating may be applied to cover the edge bond, the device, and/or the substrate. In some implementations, the coating may be applied in a manner similar to the sealant 132 in FIG. 10B. As described in Section 3, the coating may provide, for example, a smooth surface to reduce or, in some instances, prevent the boiling of a coolant liquid in a two-phase immersion cooling system at undesirable locations on the device (e.g., the edge bond). The protective coating may be thermally insulating to reduce heat transfer to undesirable locations on the device. The protective coating may be hydrophobic and/or oleophobic to repel water/aqueous solutions and oils, respectively, away from the portion of the electronic device covered by the coating.

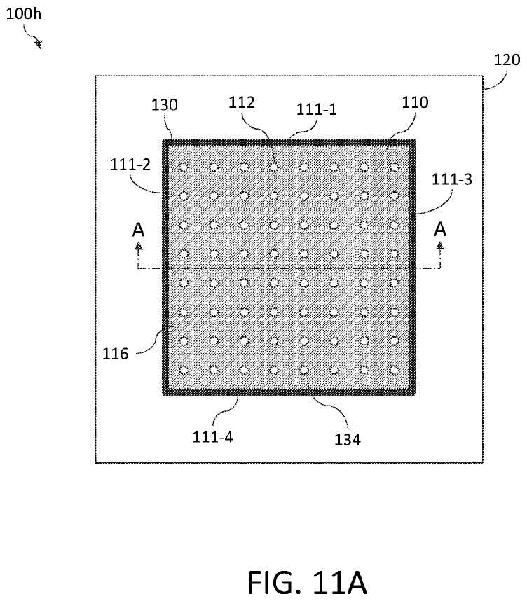

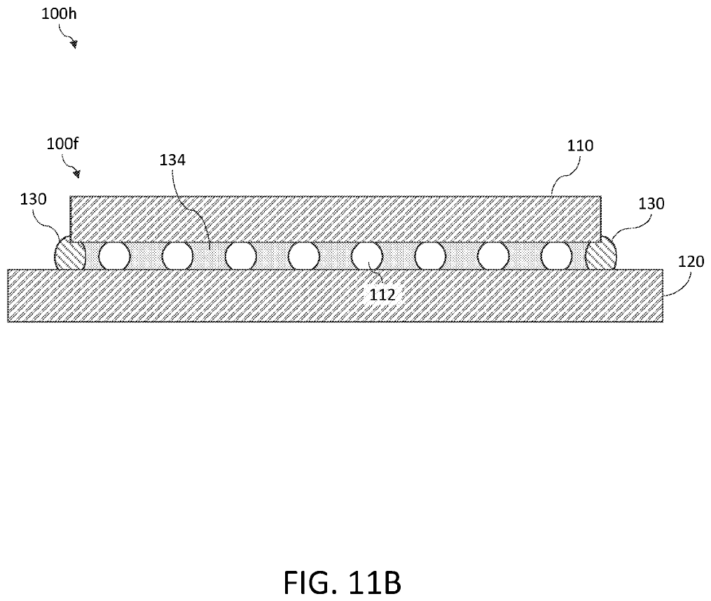

In yet another example, an electronic device may include a combination of an underfill and a sealant. For example, FIGS. 11A and 11B show an example computing system 100h that includes a sealant 130 disposed around the edges of the device 110 and an underfill 134 disposed within the cavity 116 and surrounding the BGA 112. Although manufacturing defects may occur in the underfill 134 and the sealant 130, the likelihood of defects occurring in both the underfill 134 and the sealant 130 in a manner that would allow coolant liquid to infiltrate the cavity and contaminate the BGA 112 is appreciably small, especially when compared to the risk of device failure when only the underfill or the sealant is present. It should be appreciated that, in some implementations, the sealant 130 may be substituted with a protective coating described in Section 3.

In some implementations, an electronic device may include underfill, a sealant to form an edge bond, and a protective coating covering a portion of the device (e.g., the edge bond) or the entirety of the device. Furthermore, one or more layers of sealant and/or one or more layers of a coating may be applied to the device.

### 5. Conclusion

All parameters, dimensions, materials, and configurations described herein are meant to be example and the actual parameters, dimensions, materials, and/or configurations will depend upon the specific application or applications for which the inventive teachings is/are used. It is to be understood that the foregoing embodiments are presented primarily by way of example and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein.

In addition, any combination of two or more such features, systems, articles, materials, kits, and/or methods, if such features, systems, articles, materials, kits, and/or methods are not mutually inconsistent, is included within the inventive scope of the present disclosure. Other substitutions, modifications, changes, and omissions may be made in the design, operating conditions and arrangement of respective elements of the example implementations without departing from the scope of the present disclosure. The use of a numerical range does not preclude equivalents that fall outside the range that fulfill the same function, in the same way, to produce the same result.

Also, various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All publications, patent applications, patents, and other references mentioned herein are incorporated by reference in their entirety.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B), in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A system, comprising:
a two-phase immersion cooling system, comprising:
a tank defining a tank volume configured to contain a coolant liquid; and
a computing system disposed within the tank volume and configured to be submerged in the coolant liquid, the computing system comprising:
a substrate;
a device comprising an integrated circuit;
a plurality of electrical interconnects to electrically couple the device to the substrate; and
a sealant applied to the substrate and the device;
wherein:
the sealant is disposed along at least a portion of each edge of the device such that the sealant, the device, and the substrate together form a cavity containing the plurality of electrical interconnects; and
the cavity is configured to trap one or more bubbles of a gas when the computing system is submerged in the coolant liquid.

2. The system of claim 1, wherein:
the device has a shape that is one of a rectangle or a square;
when the computing system is submerged in the coolant liquid, the device is oriented vertically and has a top edge, a right-side edge joined to the top edge, a bottom edge joined to the right-side edge, and a left-side edge joined to the bottom edge and the top edge; and
the sealant is disposed along all of the top edge, the left-side edge, and the right-side edge and along only a portion of the bottom edge to provide at least one opening into the cavity along the bottom edge.

3. The system of claim 2, wherein the at least one opening is a single opening having a width less than or equal to about 5 millimeters.

4. The system of claim 3, wherein the width is less than or equal to about 2 millimeters.

5. The system of claim 4, wherein the width is less than or equal to about 1 millimeters.

6. The system of claim 2, wherein the at least one opening is a single opening having a height less than or equal to about 10 millimeters.

7. The system of claim 6, wherein the height is less than or equal to about 5 millimeters.

8. The system of claim 7, wherein the height is less than or equal to about 2 millimeters.

9. The system of claim 2, wherein the at least one opening is a single opening centered along the bottom edge.

10. The system of claim 2, wherein the at least one opening includes two or more openings evenly distributed along the bottom edge.

11. The system of claim 2, wherein the computing system further comprises:
a plug disposed in the at least one opening to seal the at least one opening.

12. The system of claim 11, wherein the plug and the sealant are formed from different materials.

13. The system of claim 12, wherein:
the sealant comprises Zymet UA-2605-B; and
the plug comprises Zymet UA-2701.

14. The system of claim 1, wherein the sealant is disposed along all of each edge of the device.

15. The system of claim 1, wherein the sealant comprises at least one of 3M™ Scotch-Weld DP420, Zymet X2821, Zymet UA-2605-B, Zymet UVE-1017-2, Zymet CN-1780-5, Zymet X2824, or Zymet UA-2701.

16. The system of claim 1, wherein the sealant has a dielectric constant less than 1.8

17. The system of claim 1, further comprising:
an oleophobic coating, disposed at least on respective surfaces of the substrate, the device, and the sealant that form the cavity and the plurality of electrical interconnects, to repel the coolant liquid and contaminants away from the plurality of electrical interconnects.

18. The system of claim 17, wherein the oleophobic coating comprises a cross-linked fluoropolymer.

19. The system of claim 17, wherein the oleophobic coating comprises at least one of 3M™ Novec™ 2708 or 3M™ EGC-2788.

20. The system of claim 1, wherein:
the sealant is a first sealant; and
the computing system further comprises:
a second sealant disposed directly onto the first sealant.

21. The system of claim 20, wherein the first sealant and the second sealant have identical material compositions.

22. The system of claim 20, wherein the first sealant and the second sealant have different material compositions.

23. The system of claim 1, wherein the computing system further comprises:
a protective coating, disposed directly onto the sealant, to suppress boiling of the coolant liquid and repel the coolant liquid and contaminants away from the sealant.

24. The system of claim 23, wherein the protective coating comprises at least one of 3M™ Novec™ 2708, 3M™ EGC-2788, or HumiSeal® 1B73.

25. The system of claim 1, further comprising:
the coolant liquid disposed in the tank volume of the tank such that the computing system is submerged in the coolant liquid; and
the one or more bubbles disposed in the cavity of the computing system.

26. The system of claim 25, wherein the one or more bubbles comprises at least one of air or coolant vapor.

27. The system of claim 1, wherein the device comprises at least one of a computer processor unit (CPU), a graphics processor unit (GPU), a data processing unit (DPU), a field-programmable gate array (FPGA), an application-specific integrated circuit (ASIC), or memory.

28. The system of claim 1, wherein the plurality of electrical interconnects comprises a ball grid array (BGA).

29. The system of claim 1, wherein the substrate comprises at least one of a printed circuit board (PCB) or a printed circuit board assembly (PCBA).

30. (canceled)

31. (canceled)

32. (canceled)

33. (canceled)

34. (canceled)

35. (canceled)

36. (canceled)

37. (canceled)

38. (canceled)

39. (canceled)

40. A computing system configured for immersion in a coolant liquid of a two-phase immersion cooling system, the computing system comprising:
a substrate;
a device, mounted to the substrate, having an integrated circuit; and
a sealant directly coupled to the substrate and the device and disposed along at least a portion of each edge of the device such that the sealant, the device, and the substrate together form a cavity configured to trap one or more bubbles of a gas when the computing system is submerged in the coolant liquid.

41. The computing system of claim 40, wherein:
the device has a shape that is one of a rectangle or a square;
when the computing system is submerged in the coolant liquid, the device is oriented vertically and has a top edge, a right-side edge joined to the top edge, a bottom edge joined to the right-side edge, and a left-side edge joined to the bottom edge and the top edge; and
the sealant is disposed along all of the top edge, the left-side edge, and the right-side edge and only a portion of the bottom edge to provide at least one opening into the cavity along the bottom edge.

42. The computing system of claim 41, wherein the at least one opening is a single opening having a width less than or equal to about 1 millimeter.

43. The computing system of claim 40, wherein the sealant covers all edges of the device.

44. The computing system of claim 40, wherein:
the sealant is disposed around respective edges of the device such that an opening is formed into the cavity; and
the computing system further comprises:
a plug disposed in the opening to seal the opening.

45. The computing system of claim 40, wherein:
the sealant is a first sealant; and
the computing system further comprises:
a second sealant partially disposed onto the first sealant and directly coupled to the substrate and the device.

46. The computing system of claim 40, wherein the sealant comprises at least one of a two-part epoxy, or an ultraviolet curable epoxy.

47. The computing system of claim 40, further comprising:
an oleophobic coating disposed on respective surfaces of the substrate, the device, and the sealant that form the cavity.

48. The computing system of claim 47, wherein the oleophobic coating comprises a cross-linked fluoropolymer.

49. A system, comprising:
a two-phase immersion cooling system, comprising:
a tank defining a tank volume;
coolant liquid disposed within the tank volume; and
a heat exchanger partially disposed in the tank volume above the coolant liquid; and
the computing system of claim 40 submerged in the coolant liquid within the tank volume,
wherein during operation of the system, one or more bubbles of a gas are trapped in the cavity of the computing system.

50. The system of claim 49, wherein the gas is at least one of coolant vapor or air.

51. The computing system of claim 40, wherein the device is mounted to the substrate via a ball grid array.

52. A computing system configured for immersion in a coolant liquid of a two-phase immersion cooling system, the computing system comprising:
a substrate;
a device, mounted to the substrate, having an integrated circuit;
an extension plate, coupled to the device and extending from at least one edge of the device over the substrate; and
a sealant directly coupled to the substrate and the extension plate and disposed along at least a portion of each edge of the extension plate such that the sealant, the extension plate, the device, and the substrate together form a cavity configured to trap one or more bubbles of a gas when the computing system is submerged in the coolant liquid.

53. A computing system configured for immersion in a coolant liquid of a two-phase immersion cooling system, the computing system comprising:
a substrate;
a device, mounted to the substrate, having an integrated circuit;
a boiler plate, coupled to the device and extending from at least one edge of the device over the substrate, the boiler plate having a boiling enhancement coating to promote boiling of the coolant liquid; and
a sealant directly coupled to the substrate and the boiler plate and disposed along at least a portion of each edge of the boiler plate such that the sealant, the boiler plate, the device, and the substrate together form a cavity configured to trap one or more bubbles of a gas when the computing system is submerged in the coolant liquid.

54. A computing system configured for immersion in a coolant liquid of a two-phase immersion cooling system, the computing system comprising:
a substrate;
a device, mounted to the substrate, having an integrated circuit;
a boiler plate, coupled to the device, having a boiling enhancement coating to promote boiling of the coolant liquid;
a retention plate, coupled to the boiler plate, to securely couple the boiler plate and the device to the substrate; and
a sealant directly coupled to the substrate and the retention plate and disposed along at least a portion of each edge of the retention plate such that the sealant, the retention plate, the boiler plate, the device, and the substrate together form a cavity configured to trap one or more bubbles of a gas when the computing system is submerged in the coolant liquid.

55. A method for assembling a computing system for installation into a two-phase immersion cooling system, the computing system comprising a substrate and a device having an integrated circuit, the method comprising:
mounting the device to the substrate;
applying a sealant along at least a portion of each edge of the device such that the sealant, the device, and the substrate together forms a cavity configured to trap one or more bubbles of a gas when the computing system is submerged in a coolant liquid of the two-phase immersion cooling system and at least one opening into the cavity is formed;
inserting a fluoropolymer solution into the cavity through the at least one opening to form a fluoropolymer coating on respective surfaces of the substrate, the device, and the sealant that form the cavity; and
heating the computing system to a temperature of about 120° C. to cure the fluoropolymer coating.

56. The method of claim 55, wherein:
the device has a shape that is one of a rectangle or a square with a first edge, a second edge joined to the first edge, a third edge joined to the second edge, and a fourth edge joined to the third edge and the first edge; and
applying the sealant along at least a portion of each edge of the device comprises:
applying the sealant along all of the first edge, the second edge, and the third edge and only a portion of the fourth edge to provide the at least one opening along the fourth edge.

57. The method of claim 56, further comprising:
submerging the computing system into coolant liquid of a two-phase immersion cooling system such that the device is oriented vertically with the first edge being a left-side edge, the second edge being a top edge, the third edge being a right-side edge, and the fourth edge being a bottom edge.

58. The method of claim 55, wherein inserting the fluoropolymer solution into the cavity comprises:
injecting, via a syringe, the fluoropolymer solution into the cavity through the at least one opening.

59. The method of claim 55, wherein inserting the fluoropolymer solution into the cavity comprises:
dipping the computing system into a bath of fluoropolymer solution, the fluoropolymer solution entering the cavity through the at least one opening.
